(19) United States
(12) Patent Application Publication
(10) Pub. No.: US 2017/0302872 A1
(43) Pub. Date: Oct. 19, 2017

(54) SOLID-STATE IMAGING DEVICE, SIGNAL PROCESSING METHOD, AND ELECTRONIC DEVICE

(71) Applicant: SONY CORPORATION, Tokyo (JP)

(72) Inventors: Yusuke TANAKA, Kanagawa (JP); Toshifumi WAKANO, Kanagawa (JP)

(21) Appl. No.: 15/513,028

(22) PCT Filed: Sep. 17, 2015
(86) PCT No.: PCT/JP2015/076413

§ 371 Date: Mar. 21, 2017

(30) Foreign Application Priority Data
Oct. 1, 2014 (JP) 2014-203000

(51) Int. Cl. H04N 5/378; H01L 27/146; H04N 5/374

(52) U.S. Cl. CPC H04N 5/378; H04N 5/374; H01L 27/14612; H01L 27/14636; H01L 27/14643

(57) ABSTRACT

The present technology relates to a solid-state imaging device, a signal processing method, and an electronic device capable of appropriately adding signals of a plurality of pixels. —The solid-state imaging device is provided with a pixel array unit in which pixel units which output electric signals obtained by photoelectric conversion are arranged at least in a horizontal direction and a shared VSL being a vertical signal line (VSL) shared by a plurality of pixel units adjacent to each other in the horizontal direction, and the electric signals output from the plurality of pixel units which shares the shared VSL are added on the shared VSL. The present technology may be applied to an image sensors and the like which takes an image, for example.

### TECHNICAL FIELD

The present technology relates to a solid-state imaging device, a signal processing method, and an electronic device, and especially relates to the solid-state imaging device, the signal processing method, and the electronic device capable of appropriately adding signals of a plurality of pixels, for example.

### BACKGROUND ART

For example, an image sensor (solid-state imaging device) such as a complementary metal oxide semiconductor (CMOS) image sensor is mounted on a portable device and the like such as a smartphone and a moving image function equivalent to that when a digital (still/video) camera takes an image is requested. Therefore, the image sensor is required to support high-speed reading to read a signal serving as a pixel value at a high speed.

When the high-speed reading and signal amplification are performed in the image sensor, thinning reading (driving) to read the signals from the pixels while thinning is performed; in the thinning reading, the signals of a plurality of pixels might be added to be read.

In order to read the signal serving as the pixel value at a higher speed, it is required to thin more pixels by adding the signals of more pixels.

Herein, recently, technology of sharing pixels is sometimes adopted to the image sensor in order to maximize an aperture ratio of a photodiode (PD) forming the pixel in association with minimization of a pixel size.

In the technology of the sharing pixels, an area of an element other than the photodiode is made as small as possible by sharing a transistor and a floating diffusion (FD) by a plurality of pixels, so that an (opening) area of the PD is ensured.

As the technology of adding the signals of a plurality of pixels, there is floating diffusion (FD) addition and source follower (SF) addition, for example.

In the FD addition, in the FD, the signals of a plurality of pixels sharing the FD are added (for example, refer to Patent Document 1). In the SF addition, on a vertical signal line (VSL), the signals of a plurality of pixels are added (for example, refer to Patent Document 2).

### CITATION LIST

### Patent Document

### Patent Document 1: JP 2012-501578 A

### Patent Document 2: JP 2010-239317 A

### SUMMARY OF THE INVENTION

### Problems to be Solved by the Invention

In the FD addition disclosed in Patent Document 1 and the SF addition disclosed in Patent Document 2, there is a case in which it is difficult to appropriately perform the addition when the signals of the many pixels are added.

For example, when the signals of many pixels are added by the FD addition disclosed in Patent Document 1, it is required to increase the number of pixels which share the FD; however, in this case, a wiring line of the FD becomes longer and a capacity of the FD increases. As a result, amplitude of voltage obtained by the FD addition becomes smaller and conversion efficiency in converting charge obtained in the PD to voltage decreases.

Also, for example, when the signals of the pixels adjacent to each other in the horizontal direction are added, for example, by the SF addition disclosed in Patent Document 2, it is required to add the signals of the pixels on the VSLs in the adjacent columns by connecting the VSLs in the adjacent columns in the vicinity of an end of the VSL. Therefore, accuracy of a result of addition of the signals of the pixels on the VSLs in the adjacent columns is deteriorated due to an effect of wiring resistance of the VSL.

The present technology is achieved in view of such circumstances and an object thereof is to appropriately add the signals of a plurality of pixels.

### Solutions to Problems

A solid-state imaging device or an electronic device according to the present technology is a solid-state imaging device or an electronic device including a pixel array unit in which pixel units which output electric signals obtained by photoelectric conversion are arranged at least in a horizontal direction, and a shared VSL being a vertical signal line (VSL) shared by a plurality of pixel units adjacent to each other in the horizontal direction, the solid-state imaging device or the electronic device being configured such that the electric signals output from the plurality of pixel units which shares the shared VSL are added on the shared VSL.

A signal processing method according to the present technology is a signal processing method including adding electric signals output from a plurality of pixel units sharing a shared VSL on the shared VSL of a solid-state imaging device including a pixel array unit in which pixel units which output the electric signals obtained by photoelectric conversion are arranged at least in a horizontal direction, and the shared VSL being a vertical signal line (VSL) shared by the plurality of pixel units adjacent to each other in the horizontal direction.

In the present technology, electric signals output from a plurality of pixel units which share a shared VSL are added on the shared VSL being a vertical signal line (VSL) shared by the plurality of pixel units adjacent to each other in a horizontal direction of a pixel array unit in which pixel units which output the electric signals obtained by photoelectric conversion are arranged at least in the horizontal direction.

Meanwhile, the solid-state imaging device may be an independent device or may be an internal block which forms one device.

### Effects of the Invention

According to the present technology, signals of a plurality of pixels may be appropriately added.

Meanwhile, an effect is not necessarily limited to the effect herein described and may also be any effect described in this disclosure.

### BRIEF DESCRIPTION OF DRAWINGS

FIG. 1 is a block diagram illustrating a configuration example of one embodiment of a digital camera to which the present technology is applied.

FIG. 2 is a block diagram illustrating a configuration example of an image sensor 2.

FIG. 3 is a block diagram illustrating a basic configuration example of a pixel access unit 11.

FIG. 4 is a circuit diagram illustrating a configuration example of a pixel unit 41.

FIG. 5 is a cross-sectional view illustrating a configuration example of the image sensor 2.

FIG. 6 is a view illustrating a manufacturing method of manufacturing the image sensor 2.

FIG. 7 is a view illustrating an example of first SF addition.

FIG. 8 is a view illustrating an example of wiring of a transfer control line when full pixel reading and thinning reading are performed in a pixel array unit 21.

FIG. 9 is a view illustrating a first detailed configuration example of the pixel array unit 21 which performs second SF addition.

FIG. 10 is a view illustrating an example of wiring of a transfer control line TRG and a selection control line SEL when the full pixel reading and the thinning reading are performed in the pixel array unit 21.

FIG. 11 is a flowchart illustrating an example of processing of the second SF addition performed in the pixel array unit 21.

FIG. 12 is a view illustrating a first sharing method of a VSL 42′₂ₙ₋₁ by pixel units 41_{m,2n-1} and 41_{m,2n} adjacent to each other in a horizontal direction.

FIG. 13 is a view illustrating a second sharing method of the VSL 42′₂ₙ₋₁ by the pixel units 41_{m,2n-1} and 41_{m,2n} adjacent to each other in the horizontal direction.

FIG. 14 is a planar view illustrating an example of layout of the image sensor 2 which performs the second SF addition.

FIG. 15 is a planar view illustrating an example of the layout of the image sensor 2 which performs the second SF addition.

FIG. 16 is a planar view illustrating an example of the layout of the image sensor 2 which performs the second SF addition.

FIG. 17 is a planar view illustrating an example of the layout of the image sensor 2 which performs the second SF addition.

FIG. 18 is a view illustrating a second detailed configuration example of the pixel array unit 21 which performs the second SF addition.

FIG. 19 is a view illustrating an example of the wiring of the transfer control line TRG and the selection control line SEL when the full pixel reading and the thinning reading are performed in the pixel array unit 21.

FIG. 20 is a view illustrating a third detailed configuration example of the pixel array unit 21 which performs the second SF addition.

### MODE FOR CARRYING OUT THE INVENTION

<One Embodiment of Digital Camera to which Present Technology is Applied>

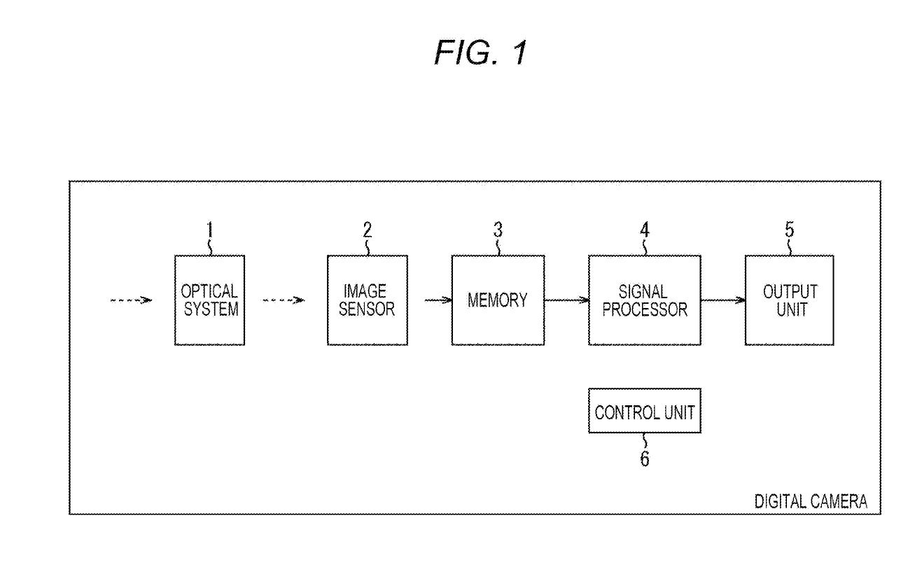

FIG. 1 is a block diagram illustrating a configuration example of one embodiment of a digital camera to which the present technology is applied.

Meanwhile, the digital camera may take both a still image and a moving image.

In FIG. 1, the digital camera includes an optical system 1, an image sensor 2, a memory 3, a signal processor 4, an output unit 5, and a control unit 6.

The optical system 1 including a zoom lens, a focus lens, a diaphragm and the like not illustrated, for example, allows external light to enter the image sensor 2.

The image sensor 2 being a CMOS image sensor, for example, receives incident light from the optical system 1, performs photoelectric conversion, and outputs image data corresponding to the incident light from the optical system 1.

The memory 3 temporarily stores the image data output from the image sensor 2.

The signal processor 4 performs processing such as noise removal and white balance adjustment, for example, as signal processing using the image data stored in the memory 3 to supply to the output unit 5.

The output unit 5 outputs the image data from the signal processor 4.

That is to say, the output unit 5 including a display (not illustrated) formed of a liquid crystal and the like, for example, displays an image corresponding to the image data from the signal processor 4 as a so-called through image.

Also, the output unit 5 including a driver (not illustrated) which drives a recording medium such a semiconductor memory, a magnetic disk, and an optical disk, for example, records the image data from the signal processor 4 in the recording medium.

The control unit 6 controls each block forming the digital camera according to user operation and the like.

In the digital camera configured in the above-described manner, the image sensor 2 receives the incident light from the optical system 1 and outputs the image data according to the incident light.

The image data output from the image sensor 2 is supplied to the memory 3 to be stored. The image data stored in the memory 3 is subjected to the signal processing by the signal processor 4 and the image data obtained as a result is supplied to the output unit 5 to be output.

<Configuration Example of Image Sensor 2>

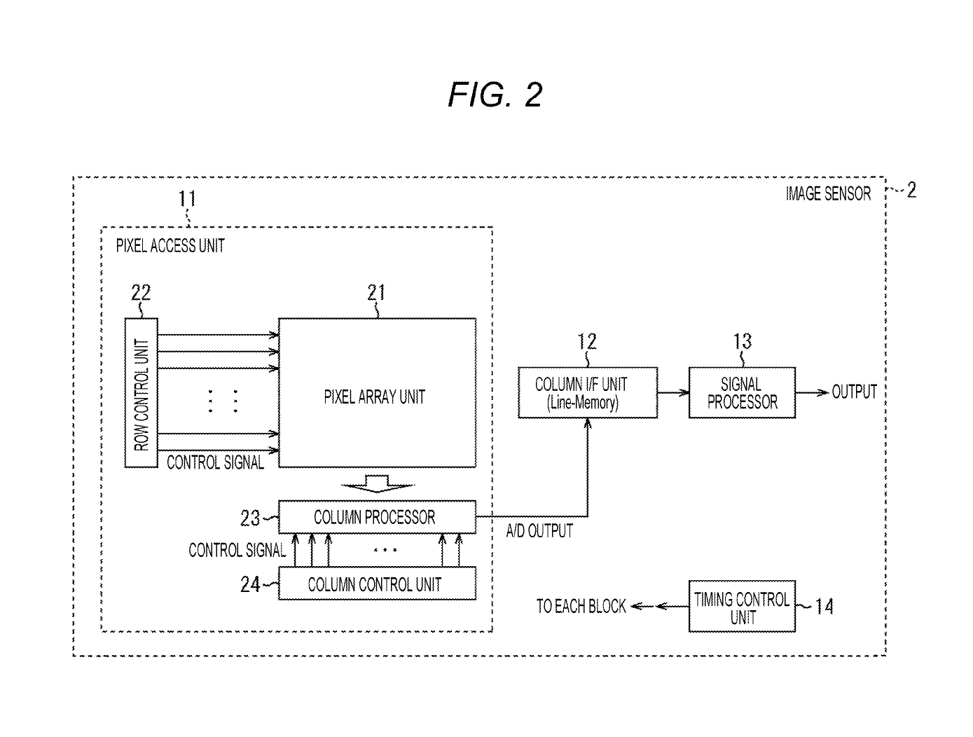

FIG. 2 is a block diagram illustrating a configuration example of the image sensor 2 in FIG. 1.

In FIG. 2, the image sensor 2 includes a pixel access unit 11, a column interface (I/F) unit 12, a signal processor 13, and a timing control unit 14.

The pixel access unit 11 including a pixel which performs the photoelectric conversion built-in accesses the pixel and obtains a pixel value serving as the image data to output.

That is to say, the pixel access unit 11 includes a pixel array unit 21, a row control unit 22, a column processor 23, and a column control unit 24.

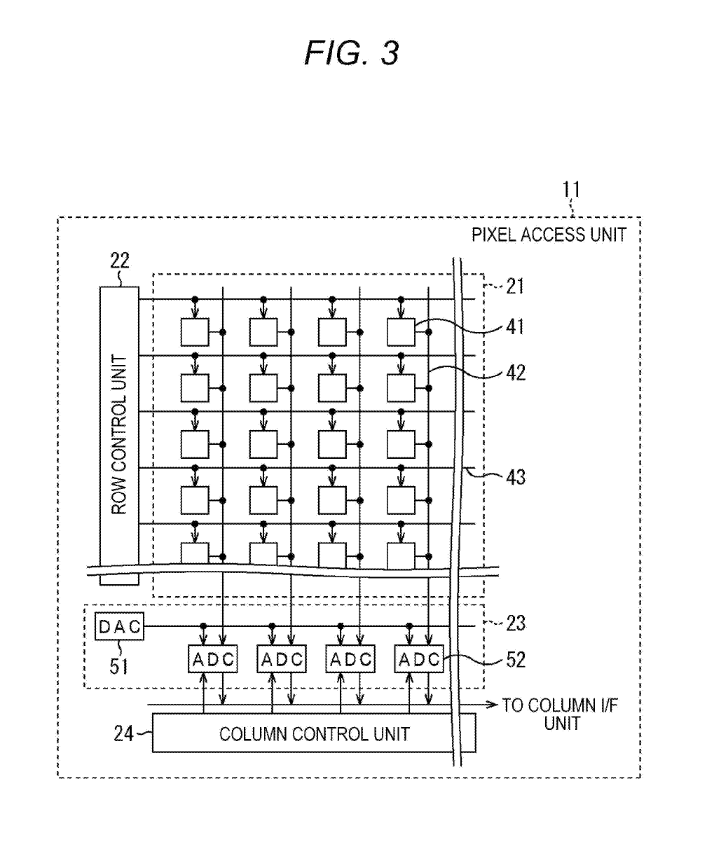

The pixel array unit 21 is formed of two or more pixel units 41 to be described later (FIG. 3) each of which includes a plurality of pixels which outputs electric signals by the photoelectric conversion arranged at least in a horizontal direction. That is to say, the pixel array unit 21 is formed of two or more pixel units 41 regularly arranged in a two-dimensional manner, for example.

The pixel array unit 21 reads the electric signal from the pixel unit 41 forming the pixel array unit 21 under control of the row control unit 22 to supply to the column processor 23.

The row control unit 22 performs access control for reading the electric signal from (the pixel included in) the pixel unit 41 of the pixel array unit 21.

The column processor 23 performs processing such as analog to digital (AD) conversion of the electric signal (voltage) supplied from the pixel array unit 21 and supplies a digital signal obtained as a result to the column I/F unit 12 as the pixel value.

The column control unit 24 performs column control being the control for supplying (outputting) the pixel value obtained by the processing of the column processor 23 to the column I/F unit 12.

The column I/F unit 12 including a line-memory built-in temporarily stores the pixel value from (the column processor 23 of) the pixel access unit 11, thereby serving as an interface which receives the pixel value.

The signal processor 13 rearranges the pixels, corrects the center of gravity of the pixel, and performs other required signal processing by using the pixel value stored in the column I/F unit 12 to output from the image sensor 2 (for example, to the memory 3 (FIG. 1)).

The timing control unit 14 generates a timing signal to control timing of operation of each block forming the image sensor 2 and supplies the same to a required block.

<Configuration Example of Pixel Access Unit 11>

FIG. 3 is a block diagram illustrating a basic configuration example of the pixel access unit 11 in FIG. 2.

As illustrated in FIG. 2, the pixel access unit 11 includes the pixel array unit 21, the row control unit 22, the column processor 23, and the column control unit 24.

The pixel array unit 21 is formed of two or more pixel units 41 regularly arranged in a two-dimensional manner, for example.

Herein, the pixel unit 41 includes a plurality of pixels which outputs the electric signals by the photoelectric conversion; this is described later in detail.

Also, although the pixel units 41 are arranged in a matrix manner in the pixel array unit 21 in FIG. 3, in addition to this, for example, the pixel units 41 may also be arranged such that the pixel unit 41 in an even-numbered row is displaced from the pixel unit 41 in an odd-numbered row by half an interval in the horizontal direction between the pixel units 41.

In the pixel array unit 21, a VSL 42 is wired in a column direction (up and down direction).

Herein, in the pixel array unit 21, one or two VSLs 42 may be wired for one column of the pixel units 41, for example. Also in the pixel array unit 21, one VSL 42 may be wired for two columns of the pixel units 41, for example. Furthermore, in the pixel array unit 21, three VSLs 42 may be wired for two columns of the pixel units 41, for example.

FIG. 3 illustrates a case in which one VSL 42 is wired for one column of the pixel units 41.

The VSL 42 is connected to the pixel units 41 of respective rows of the column provided on the VSL 42.

Furthermore, an end on a lower side, for example, as one end side of the VSL 42 is connected to the column processor 23. The electric signal read from the pixel unit 41 is supplied to the column processor 23 through the VSL 42.

In the pixel array unit 21, a row signal line 43 is wired in a row direction (right and left direction) for each row of the pixel units 41 and the row control unit 22 performs the access control on the pixel units 41 of each row by supplying a control signal (allowing the same to flow) to the row signal line 43.

The column processor 23 includes a digital analog converter (DAC) 51 and one or more AD converters (ADCs) 52.

The DAC 51 performs DA conversion, thereby generating an analog reference signal having a period in which a level changes from a predetermined initial value to a predetermined final value at a constant slope such as a ramp signal, for example, and supplies the same to the ADC 52.

The ADC 52 compares the electric signal on the VSL 42 and the reference signal supplied from the DAC 51 and counts time required for change in level of the reference signal until levels of the electric signal and reference signal coincide with each other, thereby performing the AD conversion and the like of the electric signal.

Then, the ADC 52 outputs the pixel value being the digital electric signal obtained as a result of the AD conversion and the like to the column I/F unit 12 (FIG. 2) according to control of the column control unit 24.

Herein, if the number of (columns of) the VSLs 42 is represented by K, K ADCs 52 as many as K VSLs 42 may be provided. In this case, a kth ADC 52 (in a kth column) (k=1, 2, . . . , and K) out of the K ADCs 52 is connected to the VSL 42 in the kth column, and therefore, the AD conversion and the like of the electric signal on the VSL 42 in the kth column is performed in the kth ADC 52.

Also, the number of ADCs 52 may be smaller than K, that is to say, K/2, for example. In this case, a kth (k=1, 2, . . . , K/2) ADC 52 out of the K ADCs 52 is selectively connected to two VSLs 42, that is to say, selectively connected to the VSLs 42 in (2k−1)th and 2kth columns, for example, and alternately performs the AD conversion and the like of the electric signals on the two VSLs 42 (in a time division manner).

<Configuration Example of Pixel Unit 41>

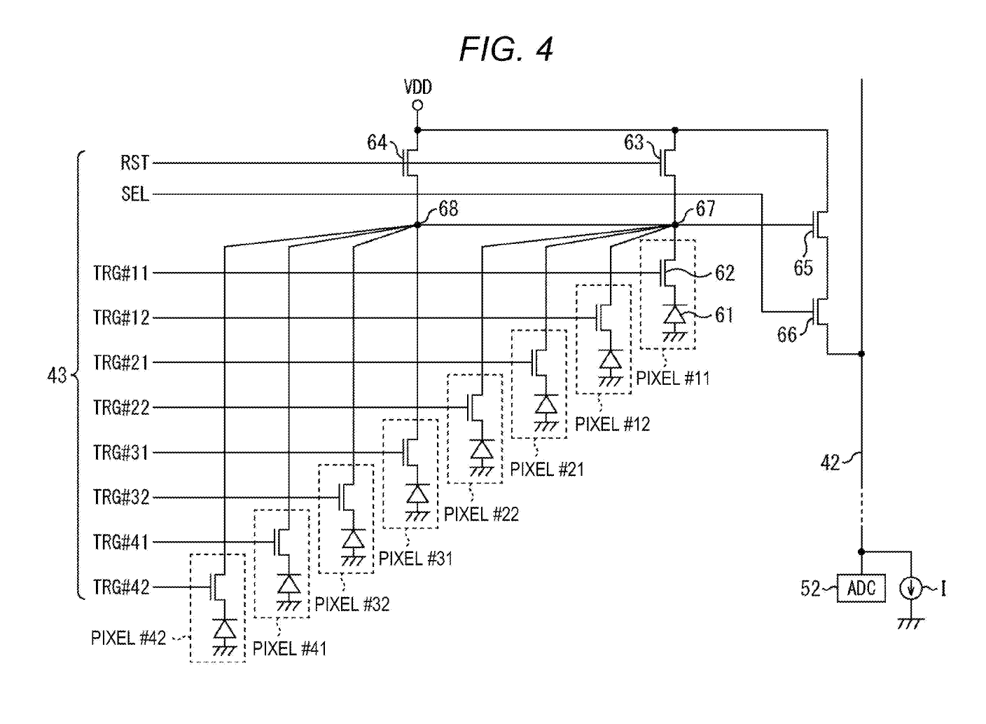

FIG. 4 is a circuit diagram illustrating a configuration example of the pixel unit 41 in FIG. 3.

The pixel unit 41 in FIG. 4 has a configuration of sharing pixels including eight pixels, for example, as a plurality of pixels.

The pixel including a photodiode (PD) 61 and a FET 62 performs the photoelectric conversion and outputs the electric signal (charge) obtained as a result.

The PD 61 being an example of a photoelectric conversion element performs the photoelectric conversion by receiving the incident light and accumulating the charge corresponding to the incident light.

An anode of the PD 61 is connected to ground (grounded) and a cathode of the PD 61 is connected to a source of the FET 62.

The FET 62 being a transistor (Tr) for transferring the charge accumulated in the PD 61 from the PD 61 to a

FD 67/68 is hereinafter also referred to as a transfer transistor 62.

The source of the transfer transistor 62 is connected to the cathode of the PD 61 and a drain of the transfer transistor 62 is connected to a gate of a FET 65 through the FD 67/68.

Also, a gate of the transfer transistor 62 is connected to the row control line 43 and a transfer pulse

TRG (#11, #12, #21, #22, #31, #32, #41, or #42) is supplied to the gate of the transfer transistor 62 through the row control line 43.

Herein, suppose that the eight pixels as the sharing pixels forming the pixel unit 41 are arranged in a configuration of two pixels by four pixels (horizontally and vertically), for example, and the pixel in an ith row from the top and a jth column from the left out of the eight pixels is hereinafter also referred to as a pixel #ij. Also, the transfer pulse TRG for the pixel #ij is hereinafter also referred to as a transfer pulse TRG#ij.

Meanwhile, there are a reset pulse RST and a selection pulse SEL to be described later in addition to the transfer pulse TRG as the control signal which the row control unit 22 (FIG. 3) allows to flow to the row control line 43 for driving the pixel unit 41 through the row control line 43 (access control).

In addition to the eight pixels as the sharing pixels, the pixel unit 41 includes field effect transistors (FETs) 63, 64, 65, and 66, and the FDs 67 and 68 shared by the pixels.

The FET 63/64 being a transistor for resetting the charge (voltage (potential)) accumulated in the FD 67/68 is hereinafter also referred to as a reset transistor 63/64.

Drains of the reset transistors 63 and 64 are connected to a power source VDD. A source of the reset transistor 63 is connected to the FD 67 and a source of the reset transistor 64 is connected to the FD 68.

Also, gates of the reset transistors 63 and 64 are connected to the row control line 43 and the reset pulse RST is supplied to the gate of the reset transistor 63 through the row control line 43.

The FET 65 being the transistor for buffering the voltage of the FDs 67 and 68 is hereinafter also referred to as an amplification transistor 65.

The gate of the amplification transistor 65 is connected to the FDs 67 and 68 and a drain of the amplification transistor 65 is connected to the power source VDD. Also, a source of the amplification transistor 65 is connected to a drain of the FET 66.

The FET 66 being the FET for selecting the output of the electric signal (voltage) to the VSL 42 is hereinafter also referred to as a selection transistor 66.

A source of the selection transistor 66 is connected to the VSL 42.

Also, a gate of the selection transistor 66 is connected to the row control line 43 and the selection pulse SEL is supplied to the gate of the selection transistor 66 through the row control line 43.

Herein, the pixel unit 41 may be formed without the selection transistor 66.

The FD 67 is an area serving as a capacity formed on a connection point between the source of the reset transistor 63 and the gate of the amplification transistor 65. The FD 68 is an area serving as a capacity formed on a connection point between the source of the reset transistor 64 and the gate of the amplification transistor 65.

The charges supplied to the FDs 67 and 68 are converted to the voltages as in capacitors.

In FIG. 4, the FD 67 is shared by four pixels #11, #12, #21, and #22, and the FD 68 is shared by other four pixels #31, #32, #41, and #42.

Meanwhile, in addition to the pixel unit 41 and the ADC 52, a current source I (not illustrated in FIG. 3) is connected to the VSL 42, and the current source I and the amplification transistor 65 form a source follower (SF) circuit. Therefore, the FDs 67 and 68 are connected to the ADC 52 through the SF circuit.

In the pixel unit 41 configured in the above-described manner, the PD 61 receives the incident light and performs the photoelectric conversion, thereby starting accumulating the charge according to a light amount of the received incident light. Meanwhile, in order to simplify the description, it is herein supposed that the selection pulse SEL is set to a H level and the selection transistor 66 is in an on-state.

When predetermined time (exposure time) elapses after the PD 61 starts accumulating the charge, the row control unit 22 (FIG. 3) temporarily sets the transfer pulse TRG (from a low (L) level) to a high (H) level.

When the transfer pulse TRG is temporarily set to the H level, the transfer transistor 62 is temporarily put into an on-state.

When the transfer transistor 62 is put into the on-state, the charge accumulated in the PD 61 is transferred to the FD 67/68 through the transfer transistor 62 to be accumulated.

The row control unit 22 temporarily sets the reset pulse RST to a H level before temporarily setting the transfer pulse TRG to the H level, thereby temporarily putting the reset transistors 63 and 64 into an on-state.

When the reset transistors 63 and 64 are put into the on-state, the FDs 67 and 68 are connected to the power source VDD, and the charges in the FDs 67 and 68 are swept to the power source VDD to be reset.

After the charges in the FDs 67 and 68 are reset, the row control unit 22 temporarily sets the transfer pulse TRG to the H level, and according to this, the transfer transistor 62 is temporarily put into the on-state as described above.

When the transfer transistor 62 is put into the on-state, the charge accumulated in the PD 61 is transferred to the reset FD 67/68 through the transfer transistor 62 to be accumulated.

Then, the voltage (potential) corresponding to the charge accumulated in the FD 67/68 is output to the VSL 42 as signal line voltage (electric signal) through the amplification transistor 65 and the selection transistor 66.

In the ADC 52 connected to the VSL 42, a reset level being the signal line voltage immediately after the pixel unit 41 is reset is subjected to the AD conversion.

Furthermore, in the ADC 52, a signal level (including the reset level and the level serving as the pixel value) being the signal line voltage (voltage corresponding to the charge accumulated in the PD 61 and transferred to the FD 67) after the transfer transistor 62 is temporarily put into the on-state is subjected to the AD conversion.

Then, in the ADC 52, correlated double sampling (CDS) to obtain difference between an AD conversion result of the reset level and an AD conversion result of the signal level as the pixel value is performed and the electric signal obtained as a result of the CDS is output to the column I/F unit 12 (FIG. 2) as the pixel value.

The pixel value is read from the pixel of the pixel unit 41 in the above-described manner.

When full pixel reading to read the pixel value from each pixel included in each pixel unit 41 of the pixel array unit 21 is performed, the row control unit 22 reads the signals in turn from the eight pixels by putting the transfer transistors 62 of the eight pixels included in the pixel unit 41 into the on-state in turn, for example.

Meanwhile, in order to simplify the description, the description of the CDS is hereinafter omitted in the reading of the electric signal (hereinafter, also referred to as a pixel signal) from (the pixel of) the pixel unit 41.

<Configuration Example of Image Sensor 2>

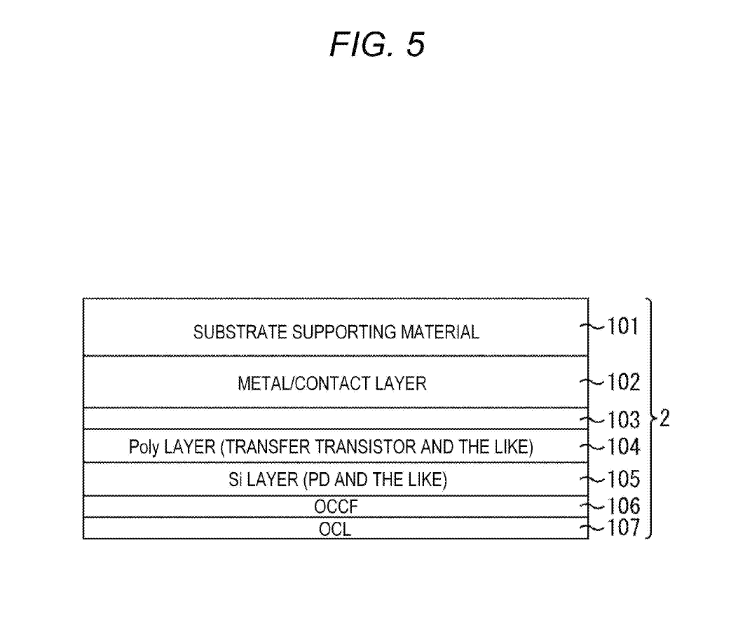

FIG. 5 is a cross-sectional view illustrating a configuration example of the image sensor 2 in FIG. 1.

The image sensor 2 is formed of a plurality of stacked layers (substrates), for example.

In FIG. 5, the image sensor 2 has a stacked structure in which a substrate supporting material 101, a metal/contact layer 102, a CS layer 103, a Poly layer 104, a Si layer, an on chip color filter (OCCF) 106, and an on chip lens (OCL) 107 are stacked from the top downward.

The image sensor 2 is a rear surface irradiation type CMOS image sensor, for example, and the substrate supporting material 101 supports the layers below the same. Also, the substrate supporting material 101 includes the circuit such as the column processor 23. The metal/contact layer 102 includes a plurality of metal layers D#i (I=1, 2, . . . ) including wiring lines and one or more contact (via) layers V#i which connects the wiring lines of a lower metal layer D#i and an upper metal layer D#i+1, and is formed of the metal layer D#i and the contact layer V#i alternatively stacked.

The CS layer 103 is a contact layer which connects the gates and the like of the FETs forming the pixel unit 41 such as the transfer transistors 63 and 64 formed in the Poly layer 102 and the lowest metal layer D#1 of the metal/contact layer 102.

The Poly layer 104 is a layer in which the gates of the FETs forming the pixel unit 41 such as the transfer transistor 63 and 64 are formed, and the Si layer 105 is a layer in which the PD 61 and the FDs 67 and 68 forming the pixel unit 41 are formed.

The OCCF 106 is a color filter of a predetermined array such as Bayer array, for example, and the OCL 107 is a lens which condenses light on the PD 61 which forms the pixel unit 41 formed on the Si layer 105.

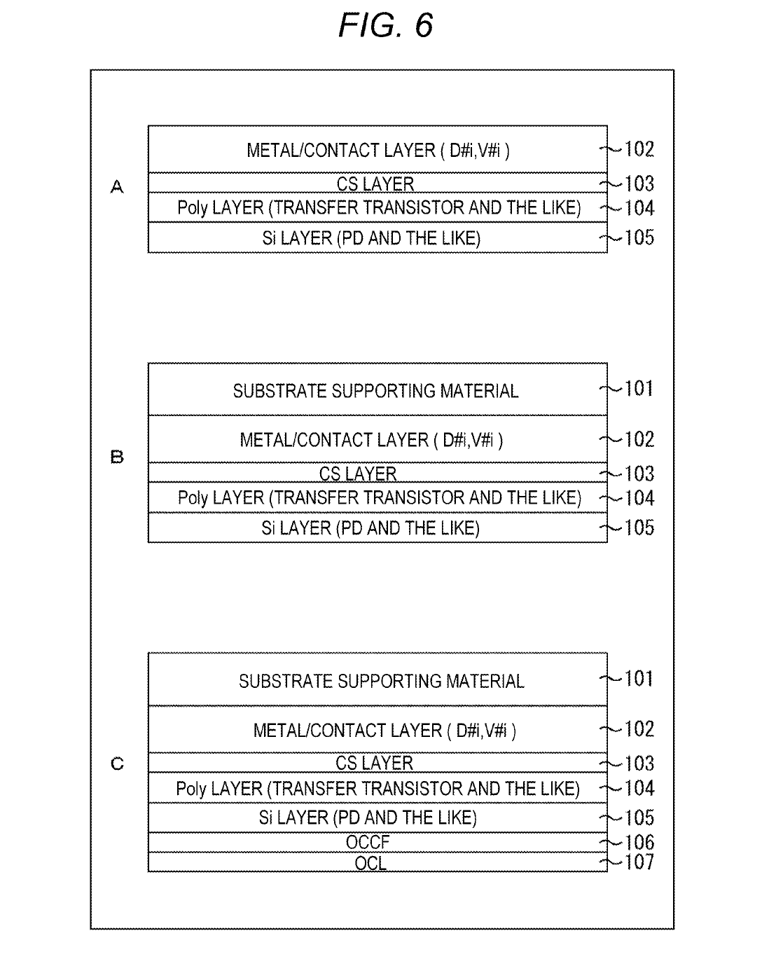

FIG. 6 is a view illustrating a manufacturing method of manufacturing the image sensor 2 in FIG. 5.

First, as illustrated in A of FIG. 6, the metal/contact layer 102, the CS layer 103, the Poly layer 105, and the Si layer 105 are formed to be stacked.

Furthermore, as illustrated in B of FIG. 6, the substrate supporting material 101 is formed above the metal/contact layer 102.

Then, as illustrated in C of FIG. 6, the OCCF 106 and the OCL 107 are formed below the Si layer 105, and the image sensor 2 is obtained.

<First SF Addition>

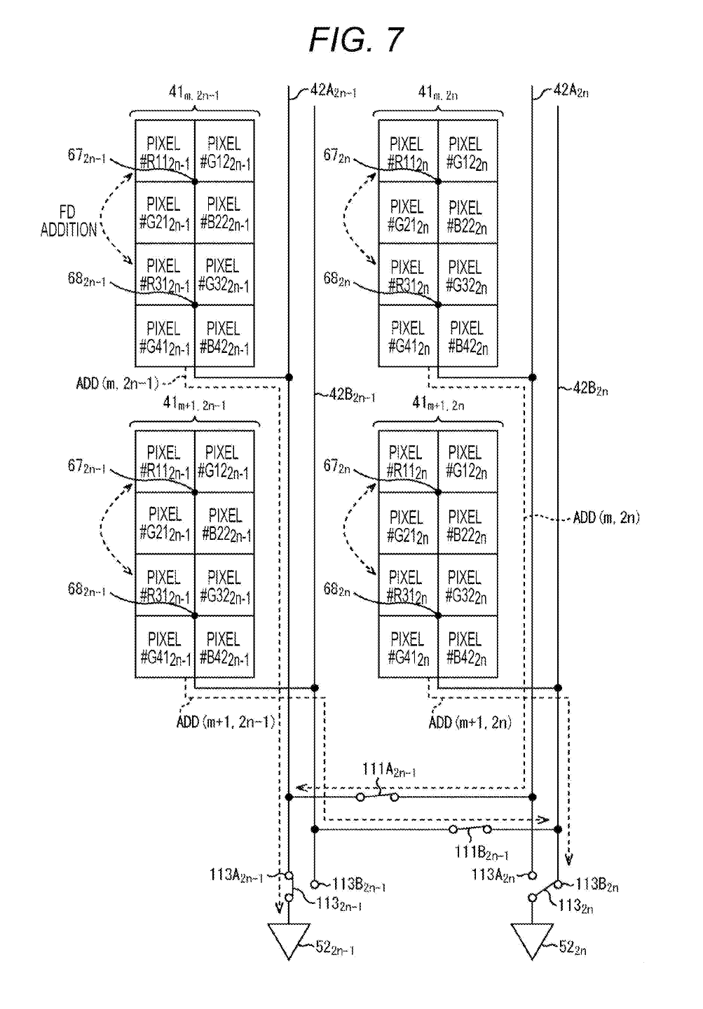

FIG. 7 is a view illustrating an example of first SF addition.

That is to say, FIG. 7 illustrates a detailed configuration example of the pixel array unit 21 which performs the first SF addition.

Hereinafter, in the pixel array unit 21, the pixel unit 41 in an mth row and an nth column (mth row from the top and nth column from the left) out of the pixel units 41 arranged in a two-dimensional manner is also referred to as a pixel unit 41_{m,n} (m,n=1, 2, . . . ).

FIG. 7 illustrates four pixels which are a pixel unit 41_{m,2n-1} in a (2n−1)th column being the odd-numbered column in an mth row, a pixel unit 41_{m+1,2n-1} in a next row, and pixel units 41_{m,2n} and 41_{m+1,2n} in a 2nth column being the even-numbered column on the right of the (2n−1)th column in the horizontal direction in the same rows as those of the pixel units 41_{m,2n-1} and 41_{m+1,2n-1}, respectively.

Also, hereinafter, the Bayer array is adopted, for example, as the array of colors of the OCCF 106 of the image sensor 2, and, it is supposed that the pixels #11 and #31 out of the eight pixels #11, #12, #21, #22, #31, #32, #41, and #42 as the sharing pixels forming the pixel unit 41 receive red (R) light, for example. Furthermore, it is supposed that the pixels #12, #21, #32, and #41 receive green (G) light and the pixels #22 and #42 receive blue (B) light.

Also, hereinafter, the pixels #ij which receive the R, G, and B lights out of the pixels #ij as the sharing pixels forming the pixel unit 41 are also referred to as pixels #Rij, #Gij, and #Bij, respectively.

Furthermore, hereinafter, the pixels #Rij, #Gij, and #Bij forming the pixel unit 41_{m,n} are also referred to as pixels #Rij_{m,n}, #Gij_{m,n}, and #Bij_{m,n}, respectively.

In the pixel array unit 21 in FIG. 7, two VSLs 42 are wired for one column of the pixel units 41.

Hereinafter, two VSLs in the nth column are also referred to as VSLs 42Aₙ and 42Bₙ.

For example, a VSL 42A₂ₙ₋₁ in the (2n−1)th column is connected to the pixel unit 41_{m,2n-1} in a certain row m in the (2n−1)th column, and a VSL 42B₂ₙ₋₁ in the (2n−1)th column is connected to the pixel unit 41_{m+1,2n-1} in a next row m+1 in the (2n−1)th column. Hereinafter, similarly, the VSL 42A₂ₙ₋₁ in the (2n−1)th column is connected to the pixel unit 41 in the odd-numbered row, for example, of the pixel units 41 in the (2n−1)th column, and the VSL 42B₂ₙ₋₁ in the (2n−1)th column is connected to the pixel unit 41 in the even-numbered row, for example, in the pixel units 41 in the (2n−1)th column.

Furthermore, in FIG. 7, the VSL 42A₂ₙ₋₁ in the (2n−1)th column and a VSL 42A₂ₙ in the 2nth column on the right thereof are connected to each other through a switch 111A₂ₙ₋₁, and the VSL 42B₂ₙ₋₁ in the (2n−1)th column and a VSL 42B₂ₙ in the 2nth column on the right thereof are connected to each other through a switch 111B₂ₙ₋₁.

Also, in the pixel array unit 21 in FIG. 7, the ADC 52 is provided for each column.

Hereinafter, the ADC 52 in the nth column is also referred to as an ADC 52ₙ.

In FIG. 7, a switch 113ₙ is provided on an input side of the ADC 52ₙ, so that the VSL 42A₂ₙ₋₁ and the VSL 42B₂ₙ₋₁ are connected to an ADC 52₂ₙ₋₁ through a switch 113₂ₙ₋₁ in the (2n−1)th column, for example.

Herein, the switch 113₂ₙ₋₁ includes terminals 113A₂ₙ₋₁ and 113B₂ₙ₋₁, and when the switch 113₂ₙ₋₁ selects the terminal 113A₂ₙ₋₁, the VSL 42A₂ₙ₋₁ is connected to the ADC 52₂ₙ₋₁, and when the switch 113₂ₙ₋₁ selects the terminal 113B₂ₙ₋₁, the VSL 42B₂ₙ₋₁ is connected to the ADC 52₂ₙ₋₁.

In the pixel array unit 21 in FIG. 7 configured in the above-described manner, when the full pixel reading is performed, for example, the switches 111A₂ₙ₋₁ and 111B₂ₙ₋₁ are turned off.

Then, at timing of reading the signal from the pixel unit 41 in the mth row, the switch 113₂ₙ₋₁ selects the terminal 113A₂ₙ₋₁ and a switch 113₂ₙ selects the terminal 113A₂ₙ.

According to this, the pixel signal obtained in the pixel #ij of the pixel unit 41_{m,2n-1} in the mth row and (2n−1)th column is supplied to the ADC 52₂ₙ₋₁ through VSL 42A₂ₙ₋₁ and the switch 113₂ₙ₋₁. Also, the pixel signal obtained in the pixel #ij of the pixel unit 41_{m,2n} in the mth row and 2nth column is supplied to an ADC 52₂ₙ through the VSL 42A₂ₙ and the switch 113₂ₙ.

On the other hand, at timing of reading the signal from the pixel unit 41 in the (m+1)th row, the switch 113₂ₙ₋₁ selects the terminal 113B₂ₙ₋₁ and the switch 113₂ₙ selects a terminal 113B₂ₙ.

According to this, the pixel signal obtained in the pixel #ij of the pixel unit 41_{m+1,2n-1} in the (m+1) th row and (2n−1)th column is supplied to the ADC 52₂ₙ₋₁ through VSL 42B₂ₙ₋₁ and the switch 113₂ₙ₋₁. Also, the pixel signal obtained in the pixel #ij of the pixel unit 41_{m+1,2n} in the (m+1)th row and 2nth column is supplied to the ADC 52₂ₙ through the VSL 42B₂ₙ and the switch 113₂ₙ.

Meanwhile, when the full pixel reading is performed, the transfer transistors 62 of the eight pixels #ij included in the pixel unit 41 are turned on in turn and the pixel signals are read from the eight pixels #ij in turn.

Next, in the pixel array unit 21 in FIG. 7, when vertical half thinning reading being thinning reading in which the pixels in the vertical direction are thinned to half is performed, for example, in the pixel unit 41, addition of the pixel signals of the same color of the two pixels in every other row in the vertical direction is performed by FD addition.

In the pixel unit 41, the FD addition of the pixel signals of the two pixels is performed by simultaneously reading the pixel signals from the two pixels.

Herein, in the pixel unit 41_{m,2n-1}, for example, as the FD addition of the vertical half thinning reading, the addition of the pixel signals of pixels #R11₂ₙ₋₁ and #R31₂ₙ₋₁, the addition of the pixel signals of pixels #G21₂ₙ₋₁ and #G41₂ₙ₋₁, the addition of the pixel signals of pixel #G12₂ₙ₋₁ and #G32₂ₙ₋₁, and the addition of the pixel signals of pixels #B22₂ₙ₋₁ and #B42₂ₙ₋₁ are performed.

For example, the FD addition as the addition of the pixel signals of the pixels #R11₂ₙ₋₁ and #R31₂ₙ₋₁ is performed by simultaneously turning on the transfer transistors 62 of the pixels #R11₂ₙ₋₁ and #R31₂ₙ₋₁.

In this case, the charges accumulated in the PDs 61 of the pixels #R11₂ₙ₋₁ and #R31₂ₙ₋₁ are transferred to the FDs 67 and 68 to be accumulated, and as a result, a signal ADD (m,2n−1) output from the FDs 67 and 68 to the VSL 42A₂ₙ₋₁ through the amplification transistor 65 and the selection transistor 66 becomes an addition signal obtained by adding the pixel signals independently read from the pixels #R11₂ₙ₋₁ and #R31₂ₙ₋₁.

As described above, the addition of the pixel signals (charges) performed by utilizing the FDs (FDs 67 and 68) is the FD addition.

In the vertical half thinning reading, (switch) control similar to that in the case of the full pixel reading is performed regarding the switches 111A₂ₙ₋₁, 111B₂ₙ₋₁, 113₂ₙ₋₁, and 113₂ₙ.

Then, the addition signal ADD(m,2n−1) obtained by the FD addition in the pixel unit 41_{m,2n-1} which is output to the VSL 42A₂ₙ₋₁ is supplied to the ADC 52₂ₙ₋₁ through the switch 113₂ₙ₋₁ as in the case of the full pixel reading.

In the vertical half thinning reading, the FD addition is similarly performed also in another pixel unit 41 and the addition signal obtained by the FD addition is output.

Next, in the pixel array unit 21 in FIG. 7, when horizontal half vertical half thinning reading in which the pixels in the horizontal direction and in the vertical direction are thinned to half is performed, for example, the addition of the pixel signals of the same color of the two pixels of every other row and the two pixels of every other column is performed by the FD addition and the SF addition.

That is to say, in the horizontal half vertical half thinning reading, the FD addition similar to that in the case of the vertical half thinning reading is performed.

For example, if the horizontal half vertical half thinning reading is performed for an R pixel (pixel which receives R light), the FD addition of the pixel signals of the pixels #R11₂ₙ₋₁ and #R31₂ₙ₋₁ is performed in the pixel unit 41_{m,2n-1}, and the FD addition of the pixel signals of the pixels #R11₂ₙ₋₁ and #R31₂ₙ₋₁ is performed in the pixel unit 41_{m+1,2n-1}.

Furthermore, the FD addition of the pixel signals of pixels #R11₂ₙ and #R31₂ₙ is performed in the pixel unit 41_{m,2n}, and the FD addition of the pixel signals of the pixels #R11₂ₙ₋₁ and #R31₂ₙ₋₁ is performed in the pixel unit 41_{m+1,2n}.

If the addition signal obtained as a result of the FD addition in the pixel unit 41_{m,n} is represented as ADD(m,n), the addition signal ADD(m,2n−1) obtained by the FD addition in the pixel unit 41_{m,2n-1} is output from the pixel unit 41_{m,2n-1} to the VSL 42A₂ₙ₋₁. Also, an addition signal ADD(m+1,2n−1) obtained by the FD addition in the pixel unit 41_{m+1,2n-1} is output from the pixel unit 41_{m+1,2n-1} to the VSL 42B₂ₙ₋₁.

Furthermore, an addition signal ADD(m,2n) obtained by the FD addition in the pixel unit 41_{m,2n} is output from the pixel unit 41_{m,2n} to the VSL 42A₂ₙ. Also, an addition signal ADD(m+1, 2n) obtained by the FD addition in the pixel unit 41_{m+1,2n} is output from the pixel unit 41_{m+1,2n} to the VSL 42B₂ₙ.

In the horizontal half vertical half thinning reading, the switches 111A₂ₙ₋₁ and 111B₂ₙ₋₁ are turned on. Furthermore, the switch 113₂ₙ₋₁ selects the terminal 113A₂ₙ₋₁ and the switch 113₂ₙ selects the terminal 113B₂ₙ.

When the switch 111A₂ₙ₋₁ is turned on, the VSLs 42A₂ₙ₋₁ and 42A₂ₙ are connected to each other, and as a result, the SF addition in which the addition signal ADD(m,2n−1) of the pixel unit 41_{m,2n-1} output to the VSL 42A₂ₙ₋₁ and the addition signal ADD(m,2n) of the pixel unit 41_{m,2n} output to the VSL 42A₂ₙ are added on the VSLs 42A₂ₙ₋₁ and 42A₂ₙ is performed. The addition signal obtained as a result of the SF addition of the addition signals ADD(m,2n−1) and ADD(m,2n) is supplied to the ADC 52₂ₙ₋₁ through the switch 113₂ₙ₋₁.

Also, when the switch 111B₂ₙ₋₁ is turned on, the VSLs 42B₂ₙ₋₁ and 42B₂ₙ are connected to each other, and as a result, the SF addition in which the addition signal ADD(m+1,2n−1) of the pixel unit 41_{m+1,2n-1} output to the VSL 42B₂ₙ₋₁ and the addition signal ADD(m+1,2n) of the pixel unit 41_{m+1,2n} output to the VSL 42B₂ₙ are added on the VSLs 42B₂ₙ₋₁ and 42B₂ₙ is performed. The addition signal obtained as a result of the SF addition of the addition signals ADD(m+1,2n−1) and ADD(m+1,2n) is supplied to the ADC 52₂ₙ through the switch 113₂ₙ.

Herein, as illustrated in FIG. 4, the VSL 42 is connected to the amplification transistor 65 of the pixel unit 41 and the current source I (FIG. 4) to form the SF circuit. Therefore, the addition of the signals as described above performed on the VSL 42 forming the SF circuit is referred to as the SF addition.

Also, the SF addition performed by connecting the different VSLs 42A₂ₙ₋₁ and 42A₂ₙ through the switch 113₂ₙ₋₁ in the above-described manner is also referred to as the first SF addition.

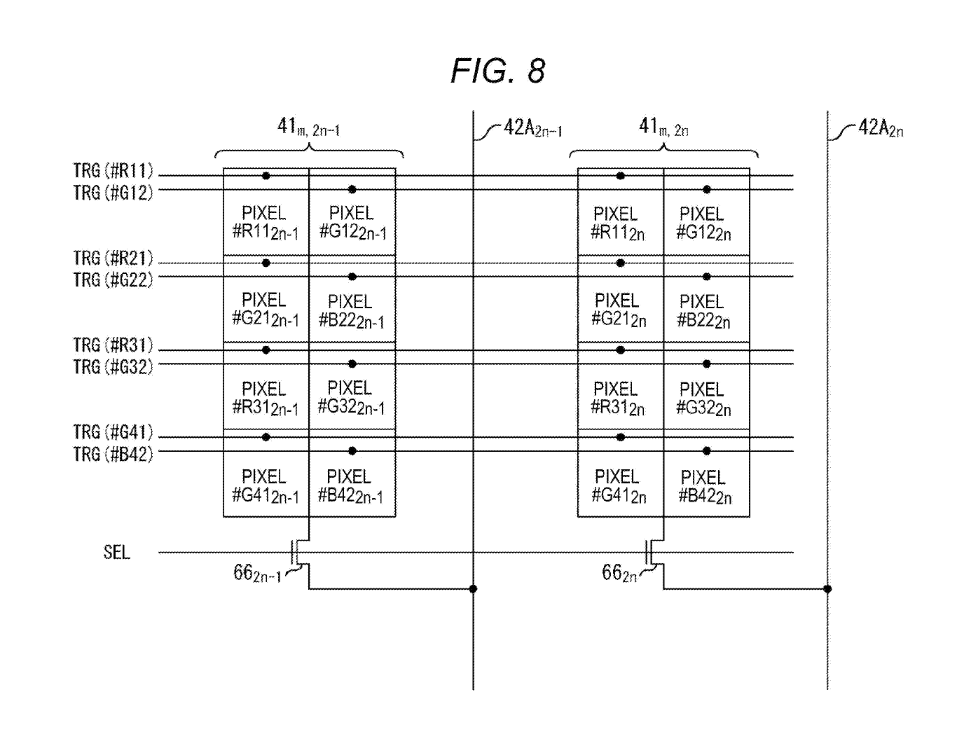

FIG. 8 is a view illustrating an example of wiring of a transfer control line when the full pixel reading and the thinning reading such as the vertical half thinning reading and the horizontal half vertical half thinning reading are performed in the pixel array unit 21 in FIG. 7.

Herein, the row control line 43 through which the transfer pulse TRG#ij flows is also referred to as a transfer control line TRG(#ij).

Also, out of the transfer control lines TRG(#ij), the transfer control line TRG(#ij) connected to the transfer transistor 62 of the pixel #Rij which receives the R light of the pixel unit 41 is also referred to as a transfer control line TRG(#Rij). Similarly, the transfer control line TRG(#ij) connected to the transfer transistor 62 of the pixel #Gij which receives the G light is also referred to as a transfer control line TRG(#Gij) and the transfer control line TRG(#ij) connected to the transfer transistor 62 of the pixel #Bij which receives the B light is also referred to as a transfer control line TRG(#Bij).

Furthermore, hereinafter, the selection transistor 66 of the pixel unit 41_{m,n} is also referred to as a selection transistor 66ₙ and the row control line 43 through which the selection pulse SEL flows is also referred to as a selection control line SEL.

In the pixel array unit 21 in FIG. 7, when the full pixel reading and the thinning reading are performed, when focusing on the pixel units 41_{m,2n-1} and 41_{m,2n-1} in two adjacent columns in a certain m row, eight transfer control lines TRG(#R11), TRG(#G12), TRG(#G21), TRG(#B22), TRG(#R31), TRG(#G32), TRG(#G41), and TRG(#B42) as many as the sharing pixels forming the pixel unit 41 are required as illustrated in FIG. 8.

The transfer control lines TRG(#R11), TRG(#G12), TRG(#G21), TRG(#B22), TRG(#R31), TRG(#G32), TRG(#G41), and TRG(#B42) are connected to the pixels #R11, #G12, #G21, #B22, #R31, #G32, #G41, and #B42, respectively.

Then, in the full pixel reading, the transfer transistors 62 of the eight pixels #R11, #G12, #G21, #B22, #R31, #G32, #G41, and #B42 of the pixel unit 41 are turned on in turn, and according to this, the pixel signals are read in turn.

On the other hand, in the thinning reading, the transfer transistors 62 of two pixels being targets of the FD addition out of the eight pixels of the pixel unit 41 are simultaneously turned on. For example, the transfer transistors 62 of the pixels #R11 and #R31 are simultaneously turned on. According to this, the FD addition of the pixel signals of the pixels #R11 and #R31 is performed, and the addition signal obtained as a result of the FD addition is output to the VSL 42.

For example, in the pixel unit 41_{m,2n-1}, the transfer transistors 62 of the pixels #R11₂ₙ₋₁ and #R31₂ₙ₋₁ are simultaneously turned on, and according to this, the pixel signals of the pixels #R11₂ₙ₋₁ and #R31₂ₙ₋₁ are subjected to the FD addition, and the addition signal obtained as a result of the FD addition is output to the VSL 42A₂ₙ₋₁ through a selection transistor 66₂ₙ₋₁.

Meanwhile, when the number of pixels thinned in the thinning reading is increased for high-speed reading in the image sensor 2, the number of pixels the pixel signals of which are to be added increases.

In the FD addition, since only the pixels electrically connected to the FD 67/68 of the pixel unit 41 are the targets of the FD addition, in order to increase the number of pixels the pixel signals of which are to be added, it is required to increase the number of (sharing) pixels forming the pixel unit 41.

When the number of pixels forming the pixel unit 41 is increased, a capacity of an entire FD in the pixel unit 41 increases because a FD wiring line to connect a distantly located pixel to the FD 67/68 becomes longer and the number of FDs increases.

If the voltage obtained from the FD is represented as V, the capacity of the FD is represented as C, and the charge accumulated in the FD is represented as Q, from relationship of equation Q=CV, when the capacity C of the FD is large, the voltage (amplitude) V which may be taken from the FD is small and conversion efficiency to convert the charge Q obtained in the PD 61 to the voltage V decreases.

Also, in the first SF addition illustrated in FIG. 7, the pixel signals of the pixel units 41 in different columns may be added to each other, that is to say, the pixel signal of the pixel unit 41_{m,2n-1} in the (2n−1)th column and the pixel signal of the pixel unit 41_{m,2n} in the 2nth column adjacent to the pixel unit 41_{m,2n-1} in the horizontal direction may be added to each other.

However, in the first SF addition, (the transistor serving as) the switch 111A₂ₙ₋₁ which connects the VSL 42A₂ₙ₋₁ in the (2n−1)th column to the VSL 42A₂ₙ₋₁ in the 2nth column is required, for example, for the thinning reading.

Also, the switch 111A₂ₙ₋₁ which connects the VSL 42A₂ₙ₋₁ in the (2n−1)th column to the VSL 42A₂ₙ₋₁ in the 2nth column is required to be provided in the vicinity of the end of the VSL 42, that is to say, in the vicinity of the end to which the ADC 52 is connected of the VSL 42, for example, in order not to interfere with the wiring of the VSL 42.

In the first SF addition, the pixel signal of the pixel unit 41_{m,2n-1} in the (2n−1)th column is added to the pixel signal of the pixel unit 41_{m,2n} in the 2nth column on a connection point between the VSL 42A₂ₙ₋₁ in the (2n−1)th column and the VSL 42A₂ₙ in the 2nth column, that is to say, on the switch 111A₂ₙ₋₁ provided in the vicinity of the ends of the VSLs 42A₂ₙ₋₁ and 42A₂ₙ.

Therefore, there is a case in which the pixel signals of the pixel units 41_{m,2n-1} and 41_{m,2n} vary due to wiring resistance of the VSLs 42A₂ₙ₋₁ and 42A₂ₙ, so that accuracy of the addition signal obtained by the first SF addition decreases.

Therefore, second SF addition may be performed in the pixel array unit 21.

<First Detailed Configuration Example of Pixel Array Unit 21 which Performs Second SF Addition>

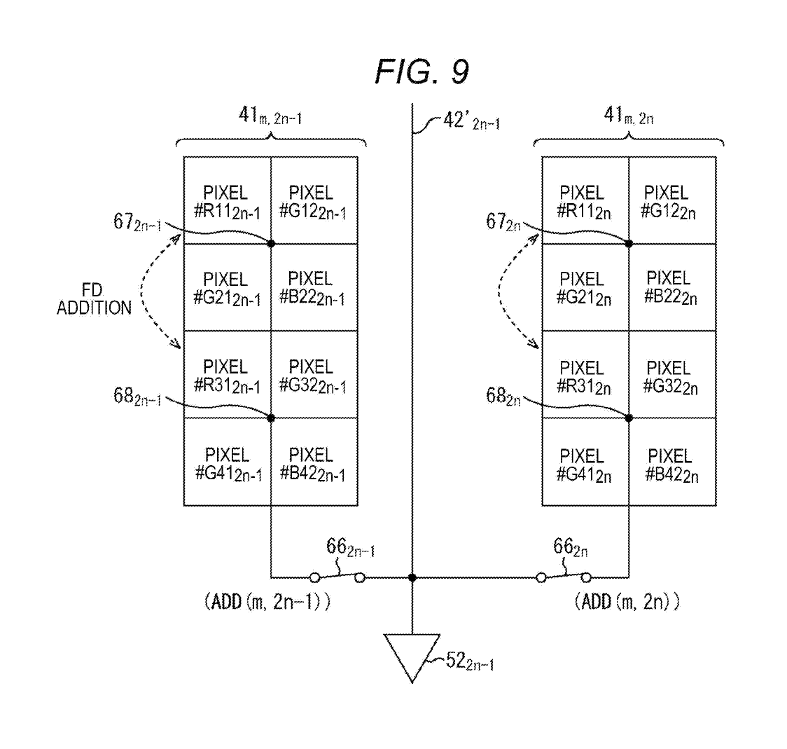

FIG. 9 is a view illustrating an example of the second SF addition.

That is to say, FIG. 9 illustrates a first detailed configuration example of the pixel array unit 21 which performs the second SF addition.

In FIG. 9, the two pixels of the pixel unit 41_{m,2n-1} in the (2n−1)th column being the odd-numbered column and the pixel unit 41_{m,2n} in the next column in the mth row are illustrated.

In the pixel array unit 21 in FIG. 9, one VSL 42 is wired for two columns of the pixel units 41.

Hereinafter, one VSL wired for two columns of the pixel unit 41_{m,2n-1} in the (2n−1)th column and the pixel unit 41_{m,2n} in the 2nth column is also referred to as a VSL 42′₂ₙ₋₁.

The pixel unit 41_{m,2n-1} in the (2n−1)th column and the adjacent pixel unit 41_{m,2n} in the 2nth column on the right of the pixel unit 41_{m,2n-1} in the horizontal direction are connected to the VSL 42′₂ₙ₋₁ to share the VSL 42′₂ₙ₋₁. Therefore, the VSL 42′₂ₙ₋₁ is hereinafter also referred to as a shared VSL.

The pixel unit 41_{m,2n-1} in the (2n−1)th column is connected to the VSL 42′₂ₙ₋₁ being the shared VSL through the selection transistor 66₂ₙ₋₁ included in the pixel unit 41_{m,2n-1}.

Similarly, the pixel unit 41_{m,2n} in the 2nth column is connected to the VSL 42′₂ₙ₋₁ being the shared VSL through a selection transistor 66₂ₙ included in the pixel unit 41_{m,2n}.

As described above, in the pixel array unit 21 in FIG. 9, one VSL 42 is wired for two columns of the pixel units 41, so that the number of VSLs 42 is half the number of columns of the pixel units 41.

In FIG. 9, one ADC 52 is provided for one VSL 42. The VSL 42′₂ₙ₋₁ being the shared VSL is connected to the ADC 52₂ₙ₋₁.

In the pixel array unit 21 in FIG. 9 configured in the above-described manner, when the full pixel reading is performed, for example, out of the odd-numbered and even-numbered columns, the selection transistor 66₂ₙ₋₁ of the pixel unit 41_{m,2n-1} in the (2n−1)th column being the odd-numbered column is turned on, and the selection transistor 66₂ₙ of the pixel unit 41_{m,2n} in the 2nth column being the even-numbered column is turned off, for example.

According to this, the pixel unit 41_{m,2n-1} out of the pixel units 41_{m,2n-1} and 41_{m,2n} sharing the VSL 42′₂ₙ₋₁ is connected to the VSL 42′₂ₙ₋₁.

Then, the transfer transistors 62 of the eight pixels #ij included in the pixel unit 41_{m,2n-1} are turned on in turn and the pixel signals are read from the eight pixels #ij in turn. The pixel signals are supplied to the ADC 52₂ₙ₋₁ through the selection transistor 66₂ₙ₋₁ of the pixel unit 41_{m,2n-1} and the VSL 42′₂ₙ₋₁.

Thereafter, the selection transistor 66₂ₙ₋₁ of the pixel unit 41_{m,2n-1} in the (2n−1)th column being the odd-numbered column is turned off, and the selection transistor 66₂ₙ of the pixel unit 41_{m,2n} in the 2nth column being the even-numbered column is turned on.

According to this, the pixel unit 41_{m,2n} out of the pixel units 41_{m,2n-1} and 41_{m,2n} sharing the VSL 42′₂ₙ₋₁ is connected to the VSL 42′₂ₙ₋₁.

Then, the transfer transistors 62 of the eight pixels #ij included in the pixel unit 41_{m,2n} are turned on in turn and the pixel signals are read from the eight pixels #ij in turn. The pixel signals are supplied to the ADC 52₂ₙ₋₁ through the selection transistor 66₂ₙ of the pixel unit 41_{m,2n} and the VSL 42′₂ₙ₋₁.

As described above, the pixel signal is output from the pixel unit 41_{m,2n-1} to the VSL 42′₂ₙ₋₁ and the pixel signal is output from the pixel unit 41_{m,2n} to the VSL 42′₂ₙ₋₁ alternately in a time division manner.

Next, in the pixel array unit 21 in FIG. 9, when the vertical half thinning reading being the thinning reading in which the pixels in the vertical direction are thinned to half is performed, for example, the addition of the pixel signals of the same color of the two pixels of every other row is performed by the FD addition in the pixel unit 41.

In the pixel unit 41, the FD addition of the pixel signals of the two pixels is performed by simultaneously reading the pixel signals from the two pixels forming the pixel unit 41 as in the case of FIG. 7.

Meanwhile, in the vertical half thinning reading, the pixel signal as the addition signal ADD(m,2n−1) obtained as a result of the FD addition is output from the pixel unit 41_{m,2n-1} in the odd-numbered column to the VSL 42′₂ₙ₋₁ and the pixel signal as the addition signal ADD(m,2n) obtained as a result of the FD addition is output from the pixel unit 41_{m,2n} in the even-numbered column to the VSL 42′₂ₙ₋₁ in a time division manner as in the case of the full pixel reading.

Then, when the pixel signal as the addition signal

ADD(m,2n−1) obtained as a result of the FD addition is output from the pixel unit 41_{m,2n-1} to the VSL 42′₂ₙ₋₁, the selection transistor 66₂ₙ₋₁ of the pixel unit 41_{m,2n-1} is turned on and the selection transistor 66₂ₙ of the pixel unit 41_{m,2n} is turned off.

On the other hand, when the pixel signal as the addition signal ADD(m,2n) obtained as a result of the FD addition is output from the pixel unit 41_{m,2n} to the VSL 42′₂ₙ₋₁, the selection transistor 66₂ₙ₋₁ of the pixel unit 41_{m,2n-1} is turned off and the selection transistor 66₂ₙ of the pixel unit 41_{m,2n} is turned on.

Next, when the horizontal half vertical half thinning reading is performed, for example, in the pixel array unit 21 in FIG. 9, the addition of the pixel signals of the same color of the two pixels of every other row and the two pixels of every other column is performed by the FD addition and the SF addition.

That is to say, in the horizontal half vertical half thinning reading, the FD addition similar to that in the case of the vertical half thinning reading is performed.

For example, if the horizontal half vertical half thinning reading is performed regarding the R pixel (pixel which receives the R light), in the pixel unit 41_{m,2n-1}, the FD addition of the pixel signals of the pixels #R11₂ₙ₋₁ and #R31₂ₙ₋₁ is performed and the addition signal ADD(m,2n−1) obtained by the FD addition is output.

Also, in the pixel unit 41_{m,2n}, the FD addition of the pixel signals of the pixels #R11₂ₙ and #R31₂ₙ is performed and the addition signal ADD(m,2n) obtained by the FD addition is output.

Then, the SF addition of the pixel signal as the addition signal ADD(m,2n−1) output from the pixel unit 41_{m,2n-1} and the pixel signal as the addition signal ADD(m,2n) output from the pixel unit 41_{m,2n} on the right of the pixel unit 41_{m,2n-1} is performed on the VSL 42′₂ₙ₋₁ being the shared VSL shared by the pixel units 41_{m,2n-1} and 41_{m,2n} and a result of the SF addition is supplied to the ADC 52₂ₙ₋₁.

That is to say, when the SF addition is performed in the pixel array unit 21 in FIG. 9, both the selection transistors 66₂ₙ₋₁ and 66₂ₙ are turned on in the pixel unit 41_{m,2n-1} in the odd-numbered column and the pixel unit 41_{m,2n} in the even-numbered column sharing the VSL 42′₂ₙ₋₁ being the shared VSL.

According to this, both the pixel unit 41_{m,2n-1} in the odd-numbered column and the pixel unit 41_{m,2n} in the even-numbered column are connected to the VSL 42′₂ₙ₋₁ being the shared VSL, and as a result, the SF addition to add the pixel signal as the addition signal ADD(m,2n−1) output from the pixel unit 41_{m,2n-1} to the pixel signal as the addition signal ADD(m,2n) output from the pixel unit 41_{m,2n} on the VSL 42′₂ₙ₋₁ being the shared VSL is performed. The addition signal obtained by the SF addition is supplied to the ADC 52₂ₙ₋₁ connected to the VSL 42′₂ₙ₋₁.

Herein, the SF addition to add the pixel signals output from the pixel units 41_{m,2n-1} and 41_{m,2n} adjacent to each other in the horizontal direction on the VSL 42′₂ₙ₋₁ being the shared VSL shared by the pixel units 41_{m,2n-1} and 41_{m,2n} as described above is also referred to as the second SF addition.

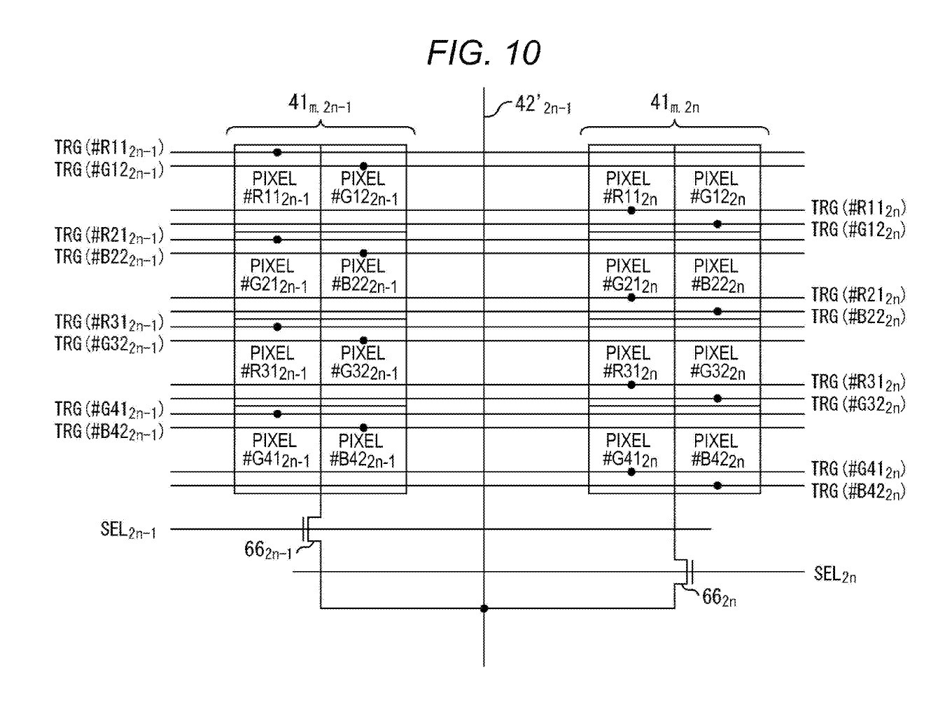

FIG. 10 is a view illustrating an example of wiring of the transfer control line TRG and the selection control line SEL when the full pixel reading and the thinning reading are performed in the pixel array unit 21 in FIG. 9.

In the pixel array unit 21 in FIG. 9, when the full pixel reading and the thinning reading are performed, when focusing on the pixel unit 41_{m,2n-1} in the odd-numbered column and the pixel unit 41_{m,2n} in the even-numbered column sharing the VSL 42′₂ₙ₋₁, 16 transfer control lines TRG (#R11₂ₙ₋₁), TRG (#G12₂ₙ₋₁), TRG (#G21₂ₙ₋₁), TRG (#B22₂ₙ₋₁), TRG (#R31₂ₙ₋₁), TRG (#G32₂ₙ₋₁), TRG (#G41₂ₙ₋₁), TRG (#B42₂ₙ₋₁), TRG (#R11₂ₙ), TRG (#G12₂ₙ), TRG (#G21₂ₙ), TRG (#B22₂ₙ), TRG (#R31₂ₙ), TRG (#G32₂ₙ), TRG (#G41₂ₙ), and TRG(#B42₂ₙ) twice as many as the sharing pixels forming the pixel unit 41 are required as illustrated in FIG. 10.

The transfer control lines TRG(#R11₂ₙ₋₁), TRG(#G12₂ₙ₋₁), TRG(#G21₂ₙ₋₁), TRG(#B22₂ₙ₋₁), TRG(#R31₂ₙ₋₁), TRG(#G32₂ₙ₋₁) TRG(#G41₂ₙ₋₁), and TRG(#B42) are connected to the pixels #R11₂ₙ₋₁, #G12₂ₙ₋₁, #G21₂ₙ₋₁, #B22₂ₙ₋₁, #R31₂ₙ₋₁, #G32₂ₙ₋₁, #G41₂ₙ₋₁, and #B42_{2,n-1} of the pixel unit 41_{m,2n-1} in the odd-numbered column, respectively.

The transfer control lines TRG (#R11₂ₙ), TRG (#G12₂ₙ), TRG (#G21₂ₙ), TRG (#B22₂ₙ), TRG (#R31₂ₙ), TRG (#G32₂ₙ), TRG (#G41₂ₙ), and TRG (#B42) are connected to the pixels #R11₂ₙ, #G12₂ₙ, #G21₂ₙ, #B22₂ₙ, #R31₂ₙ, #G32₂ₙ, #G41₂ₙ, and #B42₂ₙ of the pixel unit 41_{m,2n} in the even-numbered column, respectively.

Also, in the pixel array unit 21 in FIG. 9, when focusing on the pixel unit 41_{m,2n-1} in the odd-numbered column and the pixel unit 41_{m,2n} in the even-numbered column, as illustrated in FIG. 10, two selection control lines SEL₂ₙ₋₁ and SEL₂ₙ are required.

The selection control line SEL₂ₙ₋₁ is connected to the selection transistor 66₂ₙ₋₁ of the pixel unit 41_{m,2n-1} in the odd-numbered column and the selection control line SEL₂ₙ is connected to the selection transistor 66₂ₙ of the pixel unit 41_{m,2n} in the even-numbered column.

In the pixel array unit 21 in FIG. 9, when the full pixel reading is performed, out of the odd-numbered and even-numbered columns, the selection transistor 66₂ₙ₋₁ of the pixel unit 41_{m,2n-1} in the odd-numbered column is turned on and the selection transistor 66₂ₙ of the pixel unit 41_{m,2n} in the even-numbered column is turned off, for example.

Then, the transfer transistors 62 of the eight pixels #R11₂ₙ₋, #G12₂ₙ₋₁, #G21₂ₙ₋₁, #B22₂ₙ₋₁, #R31₂ₙ₋₁, #G32₂ₙ₋₁, #G41₂ₙ₋₁, and #B42₂ₙ₋₁ of the pixel unit 41_{m,2n-1} in the odd-numbered column are turned on in turn, and according to this, the pixel signals are read in turn.

In this case, since the selection 66₂ₙ₋₁ is turned on and the selection transistor 66₂ₙ is turned off, the pixel signals read from the eight pixels #R11₂ₙ₋₁, #G12₂ₙ₋₁, #G21₂ₙ₋₁, #B22₂ₙ₋₁, #R31₂ₙ₋₁, #G32₂ₙ₋₁, #G41₂ₙ₋₁, and #B42₂ₙ₋₁ of the pixel unit 44, are output to the VSL 42′₂ₙ₋₁ being the shared VSL through the selection transistor 66₂ₙ₋₁.

Thereafter, the selection transistor 66₂ₙ₋₁ of the pixel unit 41_{m,2n-1} in the odd-numbered column is turned off and the selection transistor 66₂ₙ of the pixel unit 41_{m,2n} in the even-numbered column is turned on.

Then, the transfer transistors 62 of the eight pixels #R11₂ₙ, #G12₂ₙ, #G21₂ₙ, #B22₂ₙ, #R31₂ₙ, #G32₂ₙ, #G41₂ₙ, and #B42₂ₙ of the pixel unit 41_{m,2n} in the even-numbered column are turned on in turn, and according to this, the pixel signals are read in turn.

In this case, since the selection 66₂ₙ₋₁ is turned off and the selection transistor 66₂ₙ is turned on, the pixel signals read from the eight pixels #R11₂ₙ, #G12₂ₙ, #G21₂ₙ, #B22₂ₙ, #R31₂ₙ, #G32₂ₙ, #G41₂ₙ, and #B42₂ₙ of the pixel unit 41_{m,2n} are output to the VSL 42′₂ₙ₋₁ being the shared VSL through the selection transistor 66₂ₙ.

On the other hand, in the thinning reading associated with the second SF addition, both the selection transistor 66₂ₙ₋₁ of the pixel unit 41_{m,2n-1} in the odd-numbered column and the selection transistor 66₂ₙ of the pixel unit 41_{m,2n} in the even-numbered column are turned on.

Furthermore, the transfer transistors 62 of the two pixels being the targets of the FD addition out of the eight pixels of the pixel unit 41 are simultaneously turned on. For example, the transfer transistors 62 of the pixels #R11 and #R31 are simultaneously turned on. According to this, the pixel signals of the pixels #R11 and #R31 are subjected to the FD addition.

For example, in the pixel unit 41_{m,2n-1} in the odd-numbered column, the transfer transistors 62 of the pixels #R11₂ₙ₋₁ and #R31₂ₙ₋₁ are simultaneously turned on, and according to this, the pixel signals of the pixels #R11₂ₙ₋₁ and #R31₂ₙ₋₁ are subjected to the FD addition, and the addition signal obtained as a result of the FD addition is output to the VSL 42′₂ₙ₋₁ being the shared VSL through the selection transistor 66₂ₙ₋₁.

Also, for example, in the pixel unit 41_{m,2n} in the even-numbered column, the transfer transistors 62 of the pixels #R11₂ₙ and #R31₂ₙ are simultaneously turned on, and according to this, the pixel signals of the pixels #R11₂ₙ and #R31₂ₙ are subjected to the FD addition, and the addition signal obtained as a result of the FD addition is output to the VSL 42′₂ₙ₋₁ being the shared VSL through the selection transistor 66₂ₙ.

As described above, the addition signal obtained by the FD addition of the pixel signals of the pixels #R11₂ₙ₋₁ and #R31₂ₙ₋₁ is output from the pixel unit 41_{m,2n-1} in the odd-numbered column to the VSL 42′₂ₙ₋₁ and the addition signal obtained by the FD addition of the pixel signals of the pixels #R11₂ₙ and #R31₂ₙ is output from the pixel unit 41_{m,2n} in the even-numbered column to the VSL 42′₂ₙ₋₁, so that the SF addition of the pixel signals (addition signals) output from the pixel units 41_{m,2n-1} and 41_{m,2n} is performed on the VSL 42′₂ₙ₋₁ being the shared VSL.

In the pixel array unit 21 in FIG. 9, as described above, the pixel unit 41_{m,2n-1} in the odd-numbered column and the pixel unit 41_{m,2n} in the even-numbered column adjacent to the pixel unit 41_{m,2n-1} in the horizontal direction share one VSL 42′₂ₙ₋₁ and the second SF addition being the addition of the pixel signals output from the pixel units 41_{m,2n-1} 41_{m,2n} is performed on the VSL 42′₂ₙ₋₁, so that it is possible to appropriately add the pixel signals output from the pixel units 41_{m,2n-1} and 41_{m,2n} as compared to the case in which the first SF addition is performed.

That is to say, according to the second SF addition, it is possible to add the pixel signals of the pixels of the pixel units 41 adjacent in the horizontal direction without increasing the pixels forming the pixel unit 41, so that it is possible to add the pixel signals with the larger number of pixels the pixel signals of which are to be added without decreasing the conversion efficiency in converting the charge Q to the voltage V as compared to the case in which the number of pixels the pixel signals of which are to be added is increased by increasing the number of (sharing) pixels forming the pixel unit 41.

Also, according to the second SF addition, the addition of the pixel signals (addition signals) output from the pixel units 41_{m,2n-1} and 41_{m,2n} is performed in the vicinity of the pixel units 41_{m,2n-1} and 41_{m,2n}, that is to say, on a connection point between the pixel units 41_{m,2n-1} and 41_{m,2n} and the VSL 42′₂ₙ₋₁ being the shared VSL, so that it is possible to inhibit deterioration in accuracy of the addition result of the second SF addition due to an effect of the wiring resistance of the VSL 42 as in the first SF addition.

Furthermore, the pixel array unit 21 in FIG. 9 in which the second SF addition is performed may perform both the full pixel reading and the thinning reading with the VSLs 42 as few as half the number of columns of the pixel unit 41.

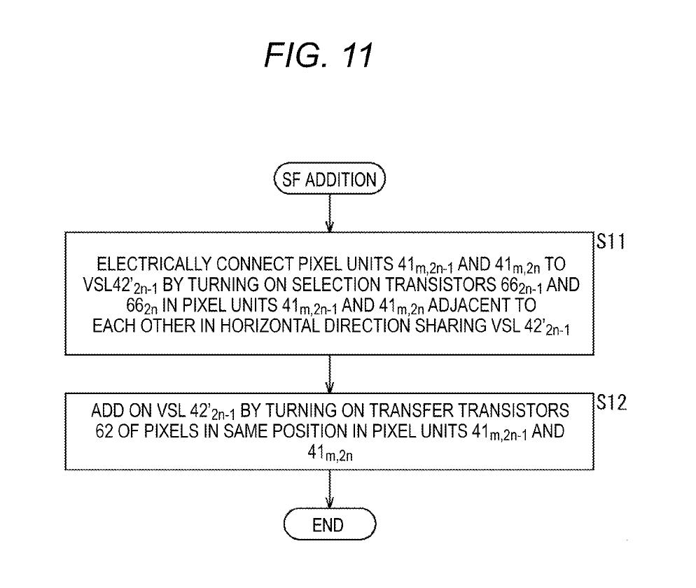

FIG. 11 is a flowchart illustrating an example of processing of the second SF addition performed in the pixel array unit 21 in FIG. 9.

At step S11, regarding each VSL 42′₂ₙ₋₁ being the shared VSL, both the selection transistors 66₂ₙ₋₁ and 66₂ₙ of the pixel units 41_{m,2n-1} and 41_{m,2n} adjacent to each other in the horizontal direction sharing the VSL 42′₂ₙ₋₁ are turned on.

According to this, both the pixel units 41_{m,2n-1} and 41_{m,2n} are electrically connected to the VSL 42′₂ₙ₋₁ being the shared VSL.

At step S12, the transfer transistors 62 of the pixels in the same position of the pixel units 41_{m,2n-1} and 41_{m,2n} are turned on.

For example, the transfer transistors 62 of the pixel #R11₂ₙ₋₁ of the pixel unit 41_{m,2n-1} and the pixel #R11₂ₙ of the pixel unit 41_{m,2n} are turned on.

In this case, the pixel signal of the pixel #R11₂ₙ₋₁ of the pixel unit 41_{m,2n-1} is output to the VSL 42′₂ₙ₋₁ being the shared VSL through the selection transistor 66₂ₙ₋₁.

Furthermore, the pixel signal of the pixel #R11₂ₙ of the pixel unit 41_{m,2n} is output to the VSL 42′₂ₙ₋₁ being the shared VSL through the selection transistor 66₂ₙ.

As a result, the second SF addition to add the pixel signal of the pixel #R11₂ₙ₋₁ of the pixel unit 41_{m,2n-1} to the pixel signal of the pixel #R11₂ₙ of the pixel unit 41_{m,2n} is performed on the VSL 42′₂ₙ₋₁ being the shared VSL.

Alternatively, at step S12, for example, the transfer transistors 62 of the pixels #R11₂ₙ₋₁ and #R31₂ₙ₋₁ of the pixel unit 41_{m,2n-1} are simultaneously turned on and the transfer transistors 62 of the pixels R11₂ₙ and #R31₂ₙ of the pixel unit 41_{m,2n} are simultaneously turned on.

In this case, the FD addition of the pixel signals of the pixels #R11₂ₙ₋₁ and #R31₂ₙ₋₁ is performed in the pixel unit 41_{m,2n-1}, and the addition signal obtained as a result of the FD addition is output to the VSL 42′₂ₙ₋₁ being the shared VSL through the selection transistor 66₂ₙ₋₁.

Similarly, the FD addition of the pixel signals of the pixels #R11₂ₙ and #R31₂ₙ is performed in the pixel unit 41_{m,2n}, and the addition signal obtained as a result of the FD addition is output to the VSL 42′₂ₙ₋₁ being the shared VSL through the selection transistor 66₂ₙ.

As a result, the second SF addition to add the addition signal obtained by the FD addition of the pixel signals of the pixels #R11₂ₙ₋₁ and #R31₂ₙ₋₁ of the pixel unit 41_{m,2n-1} to the addition signal obtained by the FD addition of the pixel signals of the pixels #R11₂ₙ and #R31₂ₙ of the pixel unit 41_{m,2n} is performed on the VSL 42′₂ₙ₋₁ being the shared VSL.

<Method of Sharing VSL>

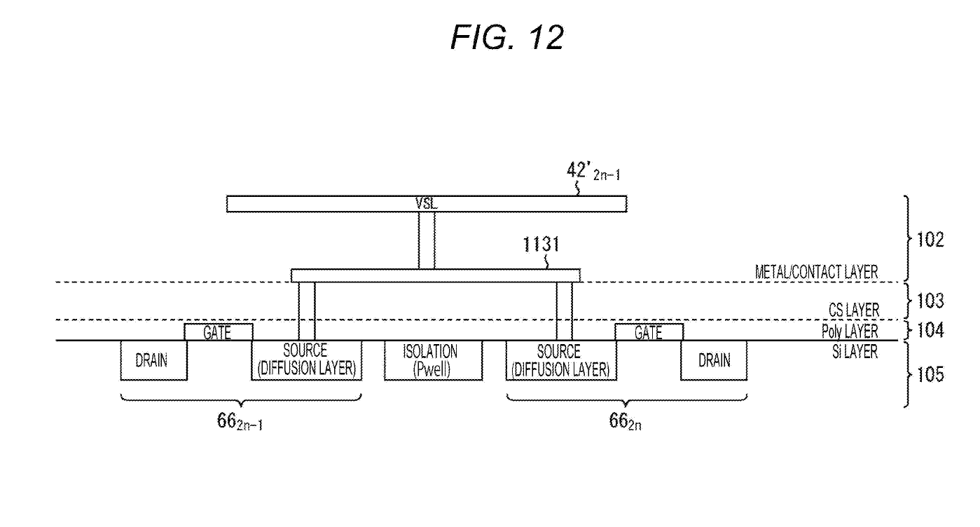

FIG. 12 is a view illustrating a first sharing method of the VSL 42′₂ₙ₋₁ by the pixel units 41_{m,2n-1} and 41_{m,2n} adjacent to each other in the horizontal direction.

That is to say, FIG. 12 is a cross-sectional view illustrating a detailed configuration example of the image sensor 2 when the VSL 42′₂ₙ₋₁ is shared by the pixel units 41_{m,2n-1} and 41_{m,2n} by the first sharing method.

Meanwhile, in the drawing, the components corresponding to those in FIG. 5 are assigned with the same reference signs, and explanation thereof is hereinafter appropriately omitted.

In FIG. 12, the metal/contact layer 102 to the Si layer 105 out of the layers from the substrate supporting layer 101 to the OCL 107 illustrated in FIG. 5 are illustrated.

The VSL 42′₂ₙ₋₁ may be shared by the pixel units 41_{m,2n-1} and 41_{m,2n} adjacent to each other in the horizontal direction by connecting diffusion layers of the selection transistors 66₂ₙ₋₁ and 66₂ₙ of the pixel units 41_{m,2n-1} and 41_{m,2n} by a wiring line 131 and connecting the wiring line 131 to the VSL 42′₂ₙ₋₁.

That is to say, in FIG. 12, the drains and the diffusion layers as the sources of the selection transistors 66₂ₙ₋₁ and 66₂ₙ are formed in the Si layer 105 and the gates of the selection transistors 66₂ₙ₋₁ and 66₂ₙ are formed in the Poly layer 104.

Furthermore, in FIG. 12, the VSL 42′₂ₙ₋₁ and the wiring line 131 are formed in the metal/contact layer 102 and the diffusion layers as the sources of the selection transistors 66₂ₙ₋₁ and 66₂ₙ are connected to the wiring line 131.

Then, the wiring line 131 is connected to the VSL 42′₂ₙ₋₁, and according to this, both the pixel unit 41_{m,2n-1} including the selection transistor 66₂ₙ₋₁ and the pixel unit 41_{m,2n} including the selection transistor 66₂ₙ are connected to the VSL 42′₂ₙ₋₁ (sharing the VSL 42′₂ₙ₋₁).

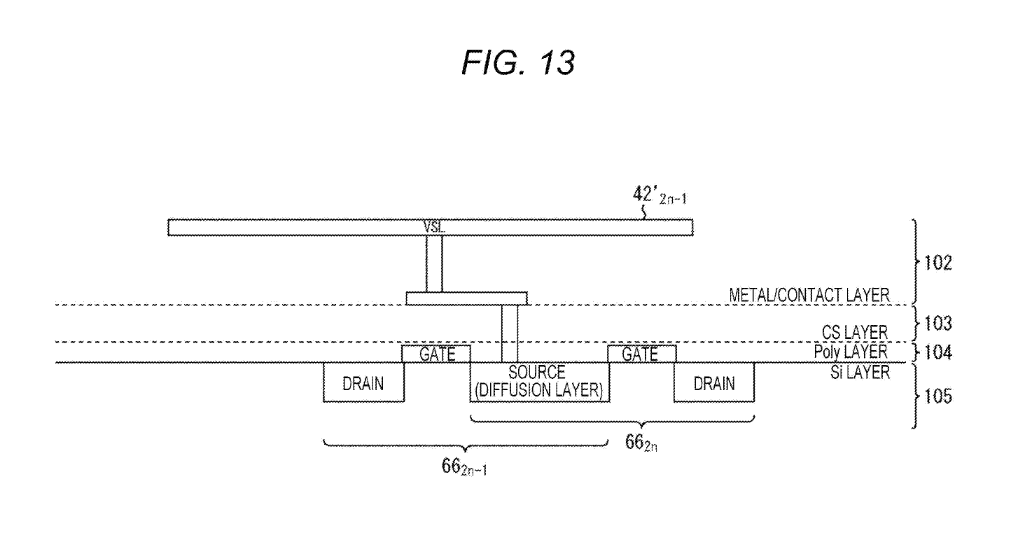

FIG. 13 is a view illustrating a second sharing method of the VSL 42′₂ₙ₋₁ by the pixel units 41_{m,2n-1} and 41_{m,2n} adjacent to each other in the horizontal direction.

That is to say, FIG. 13 is a cross-sectional view illustrating a detailed configuration example of the image sensor 2 when the VSL 42′₂ₙ₋₁ is shared by the pixel units 41_{m,2n-1} and 41_{m,2n} by the second sharing method.

Meanwhile, in the drawing, the components corresponding to those in FIG. 5 or 12 are assigned with the same reference signs, and explanation thereof is hereinafter appropriately omitted.

In FIG. 13, as in FIG. 12, the metal/contact layer 102 to the Si layer 105 out of the layers from the substrate supporting layer 101 to the OCL 107 illustrated in FIG. 5 are illustrated.

The VSL 42′₂ₙ₋₁ may be shared by the pixel units 41_{m,2n-1} and 41_{m,2n} adjacent to each other in the horizontal direction by sharing one diffusion layer as the diffusion layers as the sources of the selection transistors 66₂ₙ₋₁ and 66₂ₙ of the pixel units 41_{m,2n-1} and 41_{m,2n} and connecting the diffusion layer to the VSL 42′₂ₙ₋₁.

That is to say, in FIG. 13, the drains and the diffusion layers as the sources of the selection transistors 66₂ₙ₋₁ and 66₂ₙ are formed in the Si layer 105 and the gates of the selection transistors 66₂ₙ₋₁ and 66₂ₙ are formed in the Poly layer 104.

However, in FIG. 13, the diffusion layers as the sources of the selection transistors 66₂ₙ₋₁ and 66₂ₙ are formed so as to share the one diffusion layer.

Then, in FIG. 13, the VSL 42′₂ₙ₋₁ is formed in the metal/contact layer 102 and the one diffusion layer shared as the sources of the selection transistors 66₂ₙ₋₁ and 66₂ₙ is connected to the VSL 42′₂ₙ₋₁.

According to this, both the pixel unit 41_{m,2n-1} including the selection transistor 66₂ₙ₋₁ and the pixel unit 41_{m,2n} including the selection transistor 66₂ₙ are connected to the VSL 42′₂ₙ₋₁ (share the VSL 42′₂ₙ₋₁).

Any one of the first sharing method in FIG. 12 and the second sharing method in FIG. 13 may be adopted as the method of sharing the VSL 42′₂ₙ₋₁ by the pixel units 41_{m,2n-1} and 41_{m,2n}.

Meanwhile, in the second sharing method, the one diffusion layer is shared as the diffusion layers of the selection transistors 66₂ₙ₋₁ and 66₂ₙ of the pixel units 41_{m,2n-1} and 41_{m,2n}, so that a capacity hanging from the VSL 42′₂ₙ₋₁ becomes smaller than that in a case in which this is not shared and a high-speed image sensor 2 may be realized.

<Layout of Image Sensor 2>

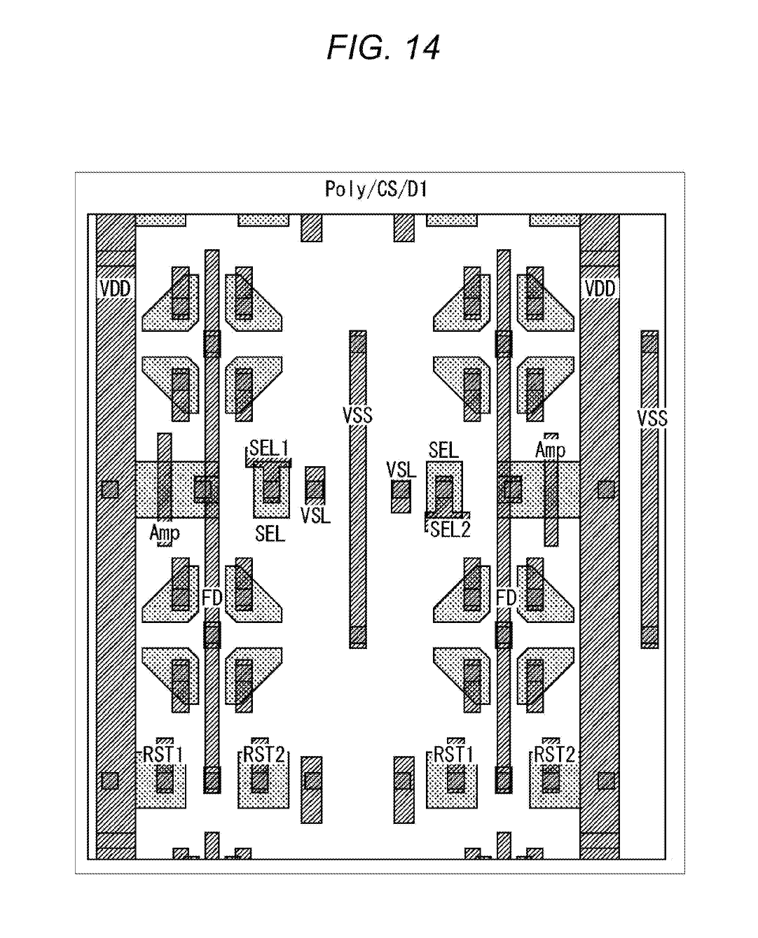

FIGS. 14, 15, 16, and 17 are planar views illustrating examples of layout of the image sensor 2 which performs the second SF addition.

Meanwhile, FIGS. 14 to 17 illustrate the examples of the layout when the pixel unit 41 includes two by four sharing pixels.

FIG. 14 illustrates the example of the layout of the Poly layer 104, the CS layer 103, and the D#1 layer of the metal/contact layer 102.

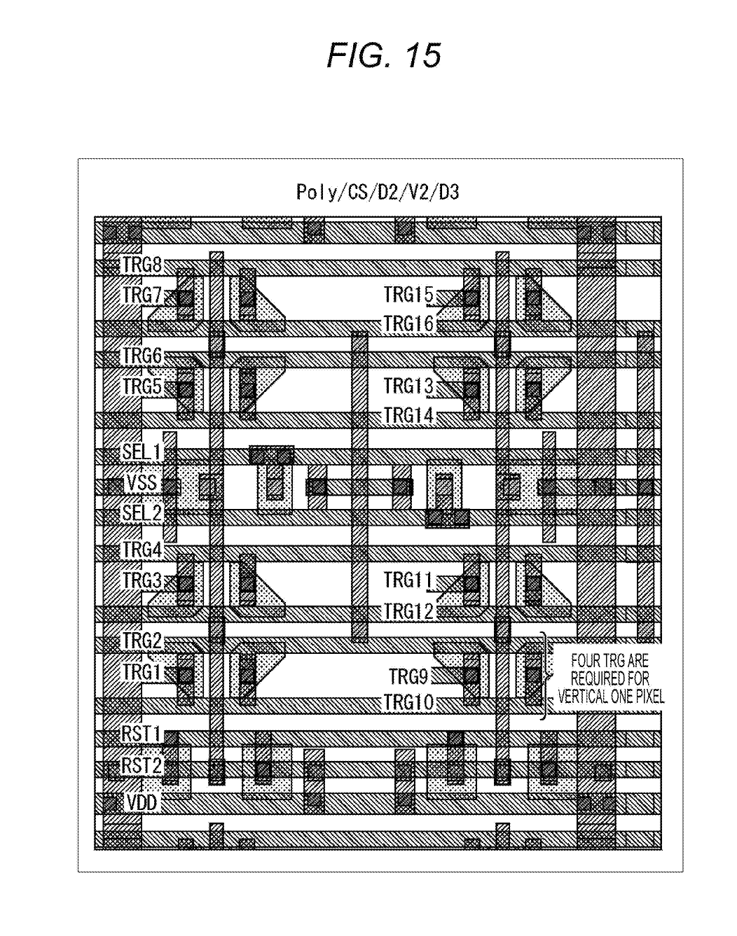

FIG. 15 illustrates the example of the layout of the Poly layer 104, the CS layer 103, and the metal layer D#2, the contact layer V#2, and the metal layer D#3 of the metal/contact layer 102.

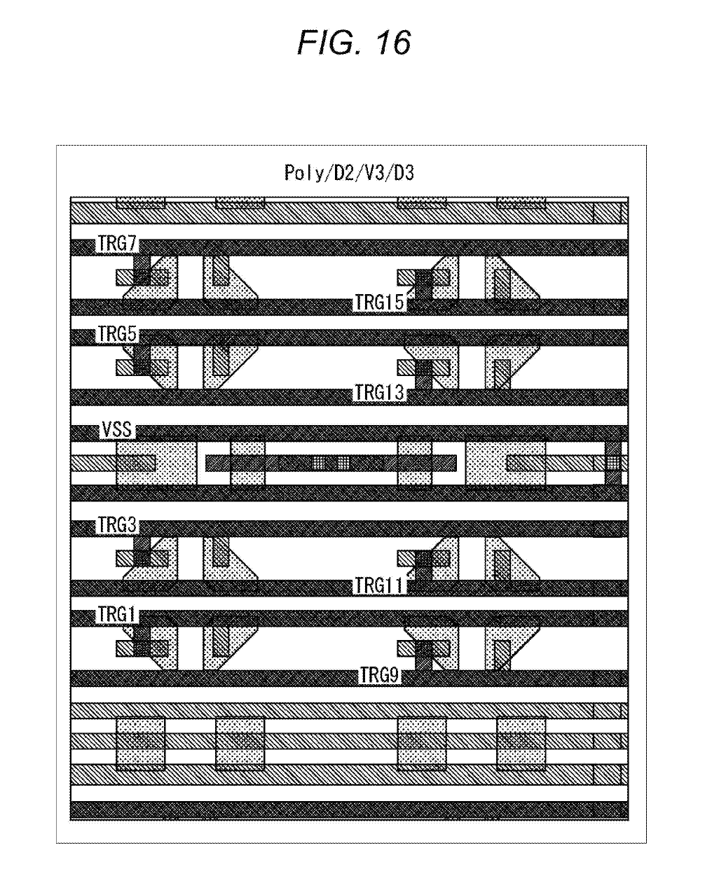

FIG. 16 illustrates the example of the layout of the Poly layer 104, and the metal layer D#2, the contact layer V#3, and the metal layer D#3 of the metal/contact layer 102.

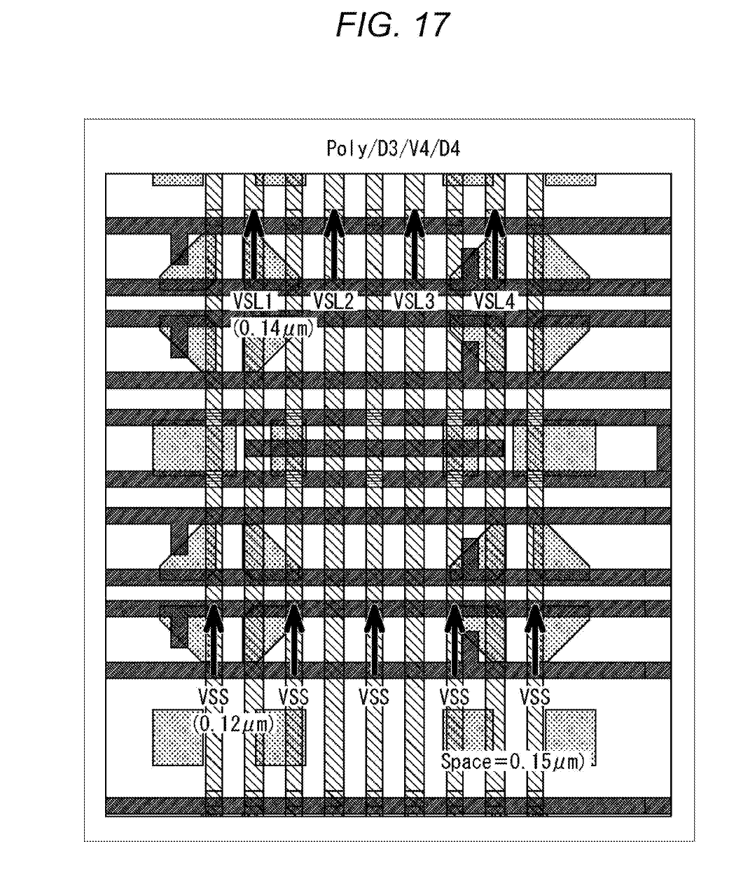

FIG. 17 illustrates the example of the layout of the Poly layer 104, and the metal layer D#3, the contact layer V#4, and the metal layer D#4 of the metal/contact layer 102.

In FIGS. 14 to 17, a dotted portion indicates the gate of the transistor (FET) forming the pixel unit 41 formed in the Poly layer 104. Especially, a substantial triangle portion in a portion in which four dotted substantial triangles are gathered indicates (the gate of) the transfer transistor 62 of each of four sharing pixels out of the two by four sharing pixels.

Two triangles in a longitudinal (vertical) direction of the portion in which the four dotted substantial triangles are gathered correspond to (the transfer transistors 62 of) the two by four sharing pixels forming one pixel unit 41.

Also, in FIGS. 14 to 17, a portion with positive slope indicates a metal wiring line.

Furthermore, in FIGS. 14 to 17, a small substantial square portion indicates the contact of the CS layer 103 or the contact of the metal/contact layer 102.

Also, in FIGS. 14 to 17, “VDD” represents (a wiring line of) the power source.

“RST1” and “RST2” represent the contacts or the wiring lines which supply the reset pulse RST to (the gates of) the reset transistors 63 and 64 and “FD” represents the FD 67 or 68.

“SEL” represents (the gate of) the selection transistor 66₂ₙ₋₁ or 66₂ₙ and “SEL1” and “SEL2” represent the contacts or wiring lines which supply the selection pulse SEL to (the gates of) the selection transistors 66₂ₙ₋₁ and 66₂ₙ.

“Amp” represents (the gate of) the amplification transistor 65 and “VSS” represents a wiring line of ground (GND).

“TRG1” to “TRG16” represent wiring lines which supply the transfer pulse TRG to (the gates of) the transfer transistors 62 of total of 16 sharing pixels of the pixel units 41_{m,2n-1} and 41_{m,2n-1} illustrated in FIG. 10.

That is to say, “TRG1” represents the transfer control line TRG(#G41₂ₙ₋₁) (row control line 43) which supplies the transfer pulse TRG to the pixel #G41₂ₙ₋₁ in the fourth row and first column of the pixel unit 41_{m,2n-1} and “TRG2” represents the transfer control line TRG(#B42₂ₙ₋₁) which supplies the transfer pulse TRG to the pixel #B42₂ₙ₋₁ in the fourth row and second column of the pixel unit 41_{m,2n-1}.

“TRG3” represents the transfer control line TRG(#R31₂ₙ₋₁) which supplies the transfer pulse TRG to the pixel #R31₂ₙ₋₁ in the third row and first column of the pixel unit 41_{m,2n-1} and “TRG4” represents the transfer control line TRG(#G32₂ₙ₋₁) which supplies the transfer pulse TRG to the pixel #G32₂ₙ₋₁ in the third row and second column of the pixel unit 41_{m,2n-1}.

“TRG5” represents the transfer control line TRG(#G21₂ₙ₋₁) which supplies the transfer pulse TRG to the pixel #G21₂ₙ₋₁ in the second row and first column of the pixel unit 41_{m,2n-1} and “TRG6” represents the transfer control line TRG(#B22₂ₙ₋₁) which supplies the transfer pulse TRG to the pixel #B22₂ₙ₋₁ in the second row and second column of the pixel unit 41_{m,2n-1}.

“TRG7” represents the transfer control line TRG(#R11₂ₙ₋₁) which supplies the transfer pulse TRG to the pixel #R11₂ₙ₋₁ in the first row and first column of the pixel unit 41_{m,2n-1} and “TRG8” represents the transfer control line TRG(#G12₂ₙ₋₁) which supplies the transfer pulse TRG to the pixel #B22₂ₙ₋₁ in the first row and second column of the pixel unit 41_{m,2n-1}.

“TRG9” represents the transfer control line TRG(#G41₂ₙ) (row control line 43) which supplies the transfer pulse TRG to the pixel #G41₂ₙ in the fourth row and first column of the pixel unit 41_{m,2n} and “TRG10” represents the transfer control line TRG(#B42₂ₙ) which supplies the transfer pulse TRG to the pixel #B42₂ₙ in the fourth row and second column of the pixel unit 41_{m,2n}.

“TRG11” represents the transfer control line TRG(#R31₂ₙ) which supplies the transfer pulse TRG to the pixel #R31₂ₙ in the third row and first column of the pixel unit 41_{m,2n} and “TRG12” represents the transfer control line TRG(#G32₂ₙ) which supplies the transfer pulse TRG to the pixel #G32₂ₙ in the third row and second column of the pixel unit 41_{m,2n}.

“TRG13” represents the transfer control line TRG(#G21₂ₙ) which supplies the transfer pulse TRG to the pixel #G21₂ₙ in the second row and first column of the pixel unit 41_{m,2n} and “TRG14” represents the transfer control line TRG(#B22₂ₙ) which supplies the transfer pulse TRG to the pixel #B22₂ₙ in the second row and second column of the pixel unit 41_{m,2n}.

“TRG15” represents the transfer control line TRG(#R11₂ₙ) which supplies the transfer pulse TRG to the pixel #R11₂ₙ in the first row and first column of the pixel unit 41_{m,2n} and “TRG16” represents the transfer control line TRG(#G12₂ₙ) which supplies the transfer pulse TRG to the pixel #B22₂ₙ in the first row and second column of the pixel unit 41_{m,2n}.

In FIGS. 14 to 17, four of the wiring lines “TRG1” to “TRG16” are wired for a width in the longitudinal direction of one pixel. For example, four wiring lines “TRG1”, “TRG2”, “TRG9”, and “TRG10” are formed in the position of the pixel in the fourth row of the two by four sharing pixels.

Meanwhile, in FIGS. 14 to 17, eight wiring lines

“TRG2”, “TRG4”, “TRG6”, “TRG8”, “TRG10”, “TRG12”, “TRG14”, and “TRG16” out of the wiring lines “TRG1” to “TRG16” are wired to the metal layer D#2 of the metal/contact layer 102. Further, the remaining eight wiring lines “TRG1”, “TRG3”, “TRG5”, “TRG7”, “TRG9”, “TRG11”, “TRG13”, and “TRG15” are wired to the metal layer D#3 of the metal/contact layer 102.

<Second Detailed Configuration Example of Pixel Array Unit 21 Which Performs Second SF Addition>

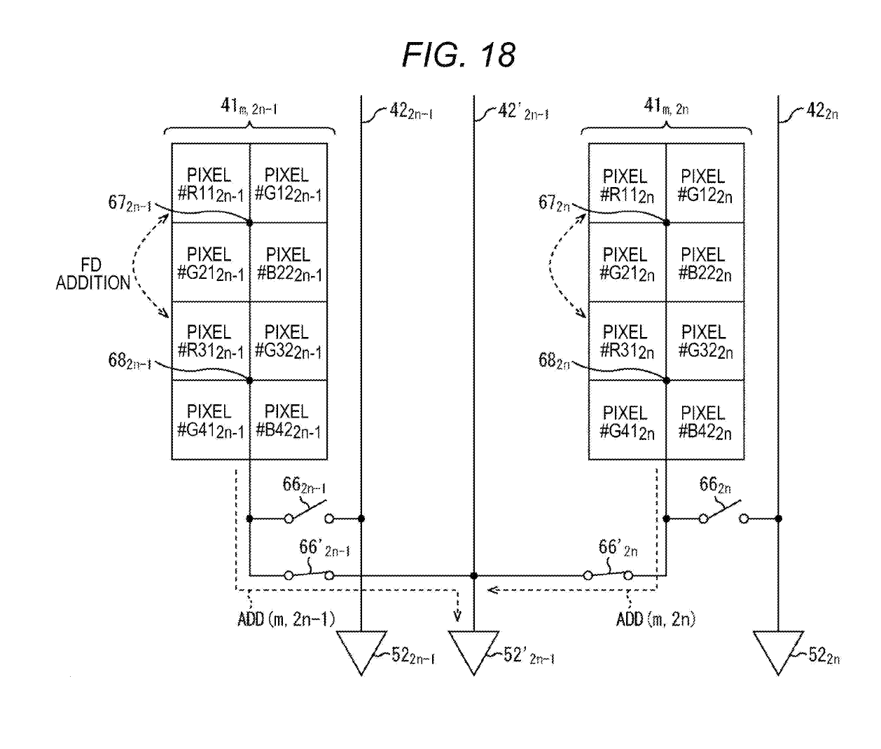

FIG. 18 is a view illustrating a second detailed configuration example of the pixel array unit 21 which performs the second SF addition.

Meanwhile, in the drawing, the components corresponding to those in FIG. 9 are assigned with the same reference signs, and explanation thereof is hereinafter appropriately omitted.

In FIG. 18, as in FIG. 9, two pixels of the pixel unit 41_{m,2n-1} in the (2n−1)th column being the odd-numbered column and the pixel unit 41_{m,2n} in the next column in the mth row are illustrated.

In the pixel array unit 21 in FIG. 18, three VSLs 42 are wired for two columns of the pixel units 41.

That is to say, in FIG. 18, the VSLs 42₂ₙ₋₁ and 42₂ₙ being the VSLs for the full pixel reading are provided in addition to the VSL 42′₂ₙ₋₁ being the shared VSL for two columns of the pixel unit 41_{m,2n-1} in the (2n−1)th column and the pixel unit 41_{m,2n} in the 2nth column.

Although the VSL 42′₂ₙ₋₁ being the shared VSL is connected to both the pixel units 41_{m,2n-1} and 41_{m,2n}, the VSL 42₂ₙ₋₁ being the VSL for the full pixel reading is connected to the pixel unit 41_{m,2n-1} and the VSL 42₂ₙ being the VSL for the full pixel reading is connected to the pixel unit 41_{m,2n}.

Therefore, in FIG. 18, one VSL 42ₙ for the full pixel reading is provided for the pixel units 41_{m,n} in one column and one VSL 42′₂ₙ₋₁ being the shared VSL (hereinafter, also referred to as the shared VSL 42′₂ₙ₋₁) is provided for the pixel units 41_{m,2n-1} and 41_{m,2n} in two columns adjacent to each other in the horizontal direction.

Furthermore, in FIG. 18, the pixel unit 41_{m,n} includes two selection transistors 66ₙ and 66′ₙ.

That is to say, the pixel unit 41_{m,2n-1} includes two selection transistors 66₂ₙ₋₁ and 66′₂ₙ₋₁ and the pixel unit 41_{m,2n} includes two selection transistors 66₂ₙ and 66′₂ₙ.

Then, the pixel unit 41_{m,2n-1} is connected to the VSL 42₂ₙ₋₁ for the full pixel reading through one selection transistor 66₂ₙ₋₁ out of the two selection transistors 66₂ₙ₋₁ and 66′₂ₙ₋₁ and is connected to the shared VSL 42′₂ₙ₋₁ through the other selection transistor 66′₂ₙ₋₁.

Similarly, the pixel unit 41_{m,2n} also is connected to the VSL 42₂ₙ for the full pixel reading through one selection transistor 66₂ₙ out of the two selection transistors 66₂ₙ and 66′₂ₙ and is connected to the shared VSL 42′₂ₙ₋₁ through the other selection transistor 66′₂ₙ.

Also, in FIG. 18, one ADC 52 is provided for one VSL 42. That is to say, the VSL 42₂ₙ₋₁ for the full pixel reading is connected to the ADC 52₂ₙ₋₁, the VSL 42₂ₙ for the full pixel reading is connected to the ADC 52₂ₙ, and the shared VSL 42′₂ₙ₋₁ is connected to an ADC 52′₂ₙ₋₁.

In the pixel array unit 21 in FIG. 18 configured in the above-described manner, when the full pixel reading is performed, for example, the selection transistors 66′₂ₙ₋₁ and 66′₂ₙ connected to the shared VSL 42′₂ₙ₋₁ are turned off and the selection transistors 66₂ₙ₋₁ and 66₂ₙ connected to the VSLs 42₂ₙ₋₁ and 42₂ₙ for the full pixel reading, respectively, are turned on in the pixel units 41_{m,2n-1} and 41_{m,2n}.

According to this, each pixel unit 41_{m,n} is connected to the VSL 42ₙ for the full pixel reading through the selection transistor 66ₙ.

Then, the transfer transistors 62 of the eight pixels #ij as the sharing pixels included in the pixel unit 41_{m,n} are turned on in turn and the pixel signals are read from the eight pixels #ij in turn. The pixel signals are supplied to the ADC 52ₙ through the selection transistor 66ₙ of the pixel unit 41_{m,n} and the VSL 42ₙ.

Next, in the pixel array unit 21 in FIG. 18, when the horizontal half vertical half thinning reading is performed, for example, the addition of the pixel signals of the same color of the two pixels of every other row and the two pixels of every other column is performed by the FD addition and the SF addition.

That is to say, the FD addition of the pixel signals of the pixels #R11₂ₙ₋₁ and #R31₂ₙ₋₁ is performed in the pixel unit 41_{m,2n-1}, and the addition signal ADD(m,2n−1) obtained by the FD addition is output. Also, the FD addition of the pixel signals of the pixels #R11₂ₙ and #R31₂ₙ is performed in the pixel unit 41_{m,2n}, and the addition signal ADD(m,2n) obtained by the FD addition is output.

Then, the second SF addition of the pixel signal as the addition signal ADD(m,2n−1) output from the pixel unit 41_{m,2n-1} and the pixel signal as the addition signal ADD(m,2n) output from the pixel unit 41_{m,2n} on the right of the pixel unit 41_{m,2n-1} is performed on the VSL 42′₂ₙ₋₁ being the shared VSL shared by the pixel units 41_{m,2n-1} and 41_{m,2n} and a result of the SF addition is supplied to the ADC 52′₂ₙ₋₁.

That is to say, in the pixel array unit 21 in FIG. 18, when the horizontal half vertical half thinning reading is performed, the selection transistors 66′₂ₙ₋₁ and 66′₂ₙ connected to the shared VSL 42′₂ₙ₋₁ are turned on and the selection transistors 66₂ₙ₋₁ and 66₂ₙ connected to the VSLs 42₂ₙ₋₁ and 42₂ₙ for the full pixel reading, respectively, are turned off in the pixel units 41_{m,2n-1} and 41_{m,2n}.

According to this, the pixel unit 41_{m,2n-1} is connected to the shared VSL 42′₂ₙ₋₁ through the selection transistor 66′₂ₙ₋₁ and the pixel unit 41_{m,2n} is connected to the shared VSL 42′₂ₙ₋₁ through the selection transistor 66′₂ₙ.

As a result, the pixel signal as the addition signal ADD(m,2n−1) output from the pixel unit 41_{m,2n-1} and the pixel signal as the addition signal ADD(m,2n) output from the pixel unit 41_{m,2n} are supplied to the shared VSL 42′₂ₙ₋₁, and the addition on the shared VSL 42′₂ₙ₋₁, that is to say, the second SF addition is performed. The addition signal obtained by the second SF addition is supplied to the ADC 52′₂ₙ₋₁ connected to the VSL 42′₂ₙ₋₁.

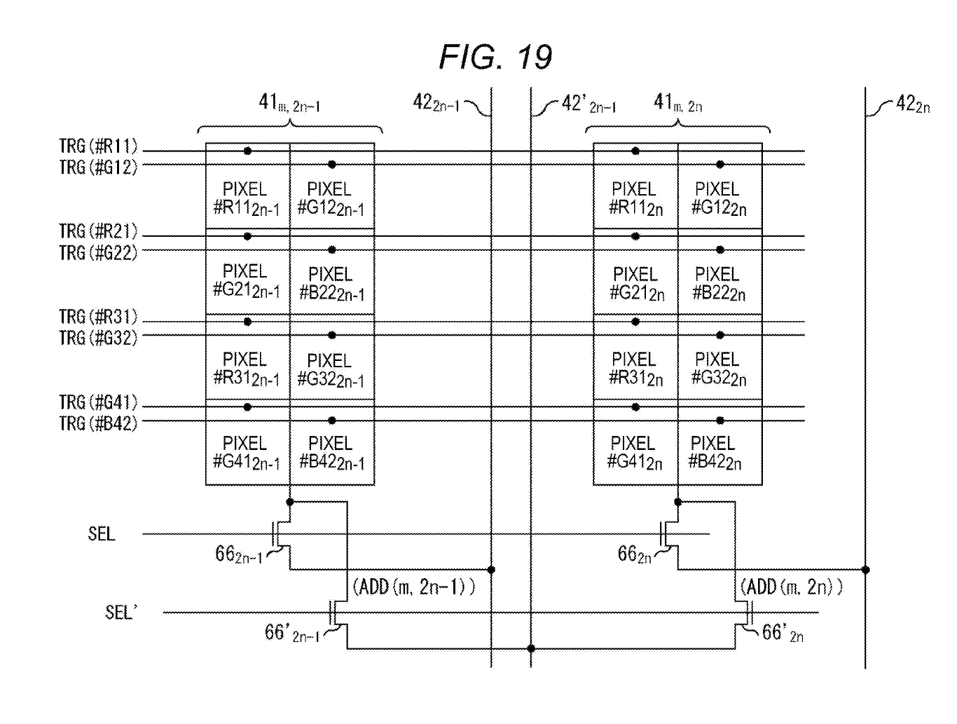

FIG. 19 is a view illustrating an example of the wiring of the transfer control line TRG and the selection control line SEL when the full pixel reading and the thinning reading are performed in the pixel array unit 21 in FIG. 18.

In the pixel array unit 21 in FIG. 18, when the full pixel reading and the thinning reading are performed, eight transfer control lines TRG(#R11), TRG(#G12), TRG(#G21), TRG(#B22), TRG(#R31), TRG(#G32), TRG(#G41), and TRG(#B42) are required as in the case in FIG. 8.

The transfer control lines TRG(#R11), TRG(#G12), TRG(#G21), TRG(#B22), TRG(#R31), TRG(#G32), TRG(#G41), and TRG(#B42) are connected to the pixels #R11, #G12, #G21, #B22, #R31, #G32, #G41, and #B42, respectively.

Also, in the pixel array unit 21 in FIG. 18, the selection control line SEL for simultaneously turning on the selection transistor 66₂ₙ₋₁ connected to the VSL 42₂ₙ₋₁ for the full pixel reading of the pixel unit 41_{m,2n-1} and the selection transistor 66₂ₙ connected to the VSL 42₂ₙ for the full pixel reading of the pixel unit 41_{m,2n} is required.

Furthermore, in the pixel array unit 21 in FIG. 18, a selection control line SEL′ for simultaneously turning on the selection transistor 66′₂ₙ₋₁ connected to the shared VSL 42′₂ₙ₋₁ of the pixel unit 41_{m,2n-1} and the selection transistor 66′₂ₙ connected to the shared VSL 42₂ₙ₋₁ of the pixel unit 41_{m,2n} is required.

In the pixel array unit 21 in FIG. 18, when the full pixel reading is performed, the selection transistors 66′₂ₙ₋₁ and 66′₂ₙ are turned off and the selection transistors 66₂ₙ₋₁ and 66₂ₙ are turned on as described above.

Then, the transfer transistors 62 of the eight pixels #R11, #G12, #G21, #B22, #R31, #G32, #G41, and #B42 of the pixel unit 41_{m,n} are turned on in turn, and according to this, the pixel signals are read in turn.

In the pixel unit 41_{m,n}, the pixel signal read from the pixel is output to the VSL 42ₙ for the full pixel reading through the selection transistor 66ₙ which is turned on.

On the other hand, in the pixel array unit 21 in FIG. 18, when the thinning reading associated with the second SF addition, that is to say, the horizontal half vertical half thinning reading is performed, for example, the selection transistors 66′₂ₙ₋₁ and 66′₂ₙ are turned on and the selection transistors 66₂ₙ₋₁ and 66₂ₙ are turned off as described above.

Furthermore, the transfer transistors 62 of the two pixels being the targets of the FD addition out of the eight pixels of the pixel unit 41 are simultaneously turned on. For example, the transfer transistors 62 of the pixels #R11 and #R31 are simultaneously turned on. According to this, the pixel signals of the pixels #R11 and #R31 are subjected to the FD addition.

For example, in the pixel unit 41_{m,2n-1} in the odd-numbered column, the transfer transistors 62 of the pixels #R11₂ₙ₋₁ and #R31₂ₙ₋₁ are simultaneously turned on, and according to this, the pixel signals of the pixels #R11₂ₙ₋₁ and #R31₂ₙ₋₁ are subjected to the FD addition, and the addition signal ADD(m,2n−1) obtained as a result of the FD addition is output to the shared VSL 42′A₂ₙ₋₁ through the selection transistor 66′₂ₙ₋₁ which is turned on.

Also, for example, in the pixel unit 41_{m,2n} in the even-numbered column, the transfer transistors 62 of the pixels #R11₂ₙ and #R31₂ₙ are simultaneously turned on, and according to this, the pixel signals of the pixels #R11₂ₙ and #R31₂ₙ are subjected to the FD addition, and the addition signal ADD(m,2n) obtained as a result of the FD addition is output to the shared VSL 42′₂ₙ₋₁ through the selection transistor 66′₂ₙ which is turned on.

According to this, the second SF addition to add the addition signal ADD(m,2n−1) obtained by the FD addition of the pixel signals of the pixels #R11₂ₙ₋₁ and #R31₂ₙ₋₁ from the pixel unit 41_{m,2n-1} to the addition signal ADD(m,2n) obtained by the FD addition of the pixel signals of the pixels #R11₂ₙ and #R31₂ₙ from the pixel unit 41_{m,2n} is performed in the shared VSL 42′₂ₙ₋₁.

Herein, as described above, in the pixel array unit 21 in FIG. 9, 16 transfer control lines TRG(#R11₂ₙ₋₁), TRG(#G12₂ₙ₋₁), TRG(#G21₂ₙ₋₁) TRG(#B22₂ₙ₋₁), TRG(#R31₂ₙ₋₁), TRG(#G32₂ₙ₋₁), TRG(#G41₂ₙ₋₁), TRG(#B42₂ₙ₋₁), TRG(#R11₂ₙ), TRG(#G12₂ₙ), TRG(#G21₂ₙ), TRG(#B22₂ₙ), TRG(#R31₂ₙ), TRG(#G32₂ₙ), TRG(#G41₂ₙ), and TRG(#B42₂ₙ) are required for the pixel units 41 in one row as illustrated in FIG. 10; however, the number of VSLs 42 is half the number of columns of the pixel units 41.

On the other hand, in the pixel array unit 21 in FIG. 18, as the VSLs 42, the shared VSLs the number of which is half the number of columns of the pixel units 41 and the VSLs for the full pixel reading as many as the number of columns of the pixel units 41 are required; however, the number of transfer control lines required for the pixel units 41 of one row is eight as described in FIG. 19.

<Third Detailed Configuration Example of Pixel Array Unit 21 Which Performs Second SF Addition>

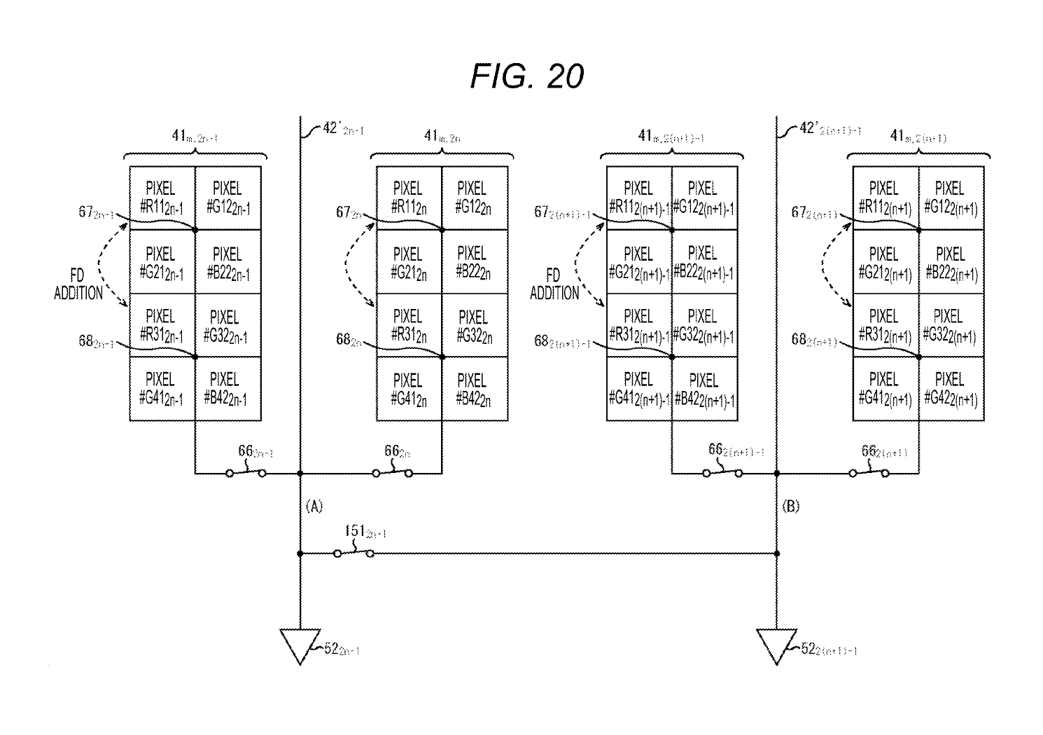

FIG. 20 is a view illustrating a third detailed configuration example of the pixel array unit 21 which performs the second SF addition.

Meanwhile, in the drawing, the components corresponding to those in FIG. 9 are assigned with the same reference signs, and explanation thereof is hereinafter appropriately omitted.

In FIG. 20, four pixel units 41_{m,2n-1}, 41_{m,2n}, 41_{m,2(n+1)-1}, and 41_{m,2(n+1)} of four columns adjacent in the horizontal direction in the mth row are illustrated.

The pixel array unit 21 in FIG. 20 is different from that in FIG. 9 in that a switch 151₂ₙ₋₁ connecting the shared VSL 42′₂ₙ₋₁ shared by the pixel units 41_{m,2n-1} and 41_{m,2n} and the shared VSL 42′₂₍ₙ₊₁₎₋₁ shared by the pixel units 41_{m,2(n+1)-1} and 41_{m,2(n+1)} is provided for the pixel units 41_{m,2n-1} to 41_{m,2(n+1)} in four columns.

The switch 151₂ₙ₋₁ corresponding to the switches 111A₂ₙ₋₁ and 111B₂ₙ₋₁ in FIG. 7 is turned on when the first SF addition is performed.

In the pixel array unit 21 in FIG. 20 configured in the above-described manner, when the full pixel reading, the vertical half thinning reading, and the horizontal half vertical half thinning reading are performed, for example, the switch 151₂ₙ₋₁ is turned off.

Then, hereinafter, the pixel signal is read as in the case in FIG. 9.

In the pixel array unit 21 in FIG. 20, horizontal quarter thinning reading in which the pixels in the horizontal direction are thinned to quarter may be performed.

In the horizontal quarter thinning reading, the switch 151₂ₙ₋₁ is turned on.

Then, hereinafter, the pixel signal is read as in the case in which the horizontal half vertical half thinning is performed in FIG. 9, for example.

Therefore, if the horizontal quarter thinning reading is performed regarding the R pixel (pixel which receives the R light), for example, the FD addition of the pixel signals of the pixels #R11₂ₙ₋₁ and #R31₂ₙ₋₁ is performed in the pixel unit 41_{m,2n-1} and the addition signal obtained by the FD addition is output. Also, in the pixel unit 41_{m,2n}, the FD addition of the pixel signals of the pixels #R11₂ₙ and #R31₂ₙ is performed and the addition signal obtained by the FD addition is output.

Then, the second SF addition of the addition signal output from the pixel unit 41_{m,2n-1} and the addition signal output from the pixel unit 41_{m,2n} is performed on the shared VSL 42′₂ₙ₋₁ shared by the pixel units 41_{m,2n-1} and 41_{m,2n} and an addition signal (A) is obtained by the second SF addition.

Also, in the pixel unit 41_{m,2(n+1)-1}, the FD addition of the pixel signals of the pixels #R11₂₍ₙ₊₁₎₋₁ and #R31₂₍ₙ₊₁₎₋₁ is performed and the addition signal obtained by the FD addition is output. Also, in the pixel unit 41_{m,2 (n+1)}, the FD addition of the pixel signals of the pixels #R11₂₍ₙ₊₁₎ and #R31₂₍ₙ₊₁₎ is performed and the addition signal obtained by the FD addition is output.

Then, the second SF addition of the addition signal output from the pixel unit 41_{m,2 (n+1)-1} and the addition signal output from the pixel unit 41_{m,2(n+1)} is performed on the shared VSL 42′₂₍ₙ₊₁₎₋₁ shared by the pixel units 41_{m,2 (n+1)-1} and 41_{m,2 (n+1)} and a second addition signal (B) is obtained by the second SF addition.

Regarding the first addition signal (A) on the shared VSL 42′₂ₙ₋₁ and the second addition signal (B) on the shared VSL 42′₂₍ₙ₊₁₎₋₁, the first SF addition is performed through the switch 151₂ₙ₋₁ which is turned on, and the addition signal obtained by the first SF addition is supplied to the ADC 52₂ₙ₋₁ and 52₂₍ₙ₊₁₎₋₁.

From above, in the pixel array unit 21 in FIG. 20, the pixel signals of the pixels in the same position of the pixel units 41_{m,2n-1}, 41_{m,2n}, 41_{m,2 (n+1)-1}, and 41_{m,2(n+1)} in the four columns are added in the horizontal direction, so that the horizontal quarter thinning reading in which the pixels in the horizontal direction are thinned to quarter may be performed.

Meanwhile, the embodiment of the present technology is not limited to the above-described embodiment and various modifications may be made without departing from the gist of the present technology.

Further, although the Bayer array is adopted as the pattern of the color filter (OCCF 106) in this embodiment, the pattern of the color filter is not limited to the Bayer array.

Furthermore, although one shared VSL 42 is shared by the pixel units 41 in two columns adjacent to each other in the horizontal direction in this embodiment, in addition to this, one shared VSL 42 may also be shared by the pixel units 41 in three of more columns adjacent to one another in the horizontal direction, for example.

Further, although one VSL 42 is shared by the pixel units 41 in two columns adjacent to each other by connecting or sharing the diffusion layer of the source of the selection transistor 66 of each of the pixel units 41 in two columns adjacent to each other in the horizontal direction in this embodiment, the VSL 42 may be shared by the pixel units 41 in two columns adjacent to each other by connecting or sharing the diffusion layer of the transistor other than the selection transistor 66.

That is to say, for example, one VSL 42 may be shared by the pixel units 41 in two columns adjacent to each other by forming the pixel unit 41 without the selection transistor 66 and connecting or sharing the diffusion layer of the source of the amplification transistor 65 of each of the pixel units 41 in two columns adjacent to each other and connecting the diffusion layer to the VSL 42.

Furthermore, although the configuration of the sharing pixels including a plurality of pixels is adopted as the configuration of the pixel unit 41 in this embodiment, the pixel unit 41 may be formed of one pixel. When the pixel unit 41 is formed of one pixel, the FD addition is not performed (cannot be performed).

Also, although the configuration of the sharing pixels of two by four pixels (horizontally and vertically) is adopted as the configuration of the pixel unit 41 in this embodiment, it is also possible to adopt the configuration other than two by four pixels, for example, two by two pixels, two by one pixels, one by two pixels, and four by two pixels as the configuration of the sharing pixels.

Furthermore, the present technology may be applied to any electronic device which may have a function of taking an image such as a personal computer (PC), a cell phone, a tablet terminal, a smartphone, a wearable camera and the like in addition to the digital camera.

The effect described in this specification is illustrative only and is not limitative; there may also be another effect.

Meanwhile, this technology may also have a following configuration.

<1>

A solid-state imaging device including:

a pixel array unit in which pixel units which output electric signals obtained by photoelectric conversion are arranged at least in a horizontal direction; and

a shared VSL being a vertical signal line (VSL) shared by a plurality of pixel units adjacent to each other in the horizontal direction,

the solid-state imaging device being configured such that the electric signals output from the plurality of pixel units which shares the shared VSL are added on the shared VSL.

<2>

The solid-state imaging device according to <1>, wherein

a pixel unit includes a plurality of pixels being sharing pixels which share a floating diffusion (FD) and outputs the electric signals obtained by the photoelectric conversion by the pixels.

<3>

The solid-state imaging device according to <2>, wherein

the pixel unit outputs an addition signal obtained by FD addition to add the electric signals obtained by two or more pixels sharing the FD by utilizing the FD.

<4>

The solid-state imaging device according to <3>, wherein

the electric signals obtained by two or more pixels arranged in a vertical direction out of the plurality of pixels included in the pixel unit are added in the FD addition.

<5>

The solid-state imaging device according to any one of <2> to <4>, wherein

the pixel unit includes a transistor including a diffusion layer, and

diffusion layers of transistors of the pixel units adjacent to each other in the horizontal direction are connected by a wiring line and the wiring line is connected to the shared VSL, so that the pixel units adjacent to each other in the horizontal direction share the shared VSL.

<6>

The solid-state imaging device according to <5>, wherein

the transistor is a selection transistor.

<7>

The solid-state imaging device according to any one of <2> to <6>, further including:

a VSL for full pixel reading to read each of the electric signals obtained by the plurality of pixels included in the pixel unit.

<8>

The solid-state imaging device according to any one of <2> to <4>, wherein

the pixel unit includes a transistor including a diffusion layer, and

one diffusion layer is shared as diffusion layers of transistors of the pixel units adjacent to each other in the horizontal direction and is connected to the shared VSL, so that the pixel units adjacent to each other in the horizontal direction share the shared VSL.

<9>

The solid-state imaging device according to <8>, wherein

the transistor is a selection transistor.

<10>

The solid-state imaging device according to <8> or <9>, further including:

a VSL for full pixel reading to read each of the electric signals obtained by the plurality of pixels included in the pixel unit.

<11>

A signal processing method including:

adding electric signals output from a plurality of pixel units sharing a shared VSL on the shared VSL of

a solid-state imaging device including:

a pixel array unit in which pixel units which output the electric signals obtained by photoelectric conversion are arranged at least in a horizontal direction; and

the shared VSL being a vertical signal line (VSL) shared by the plurality of pixel units adjacent to each other in the horizontal direction.

<12>

An electronic device including:

an optical system which condenses light; and

a solid-state imaging device which receives light and takes an image, wherein

the solid-state imaging device includes:

a pixel array unit in which pixel units which output electric signals obtained by photoelectric conversion are arranged at least in a horizontal direction; and

a shared VSL being a vertical signal line (VSL) shared by a plurality of pixel units adjacent to each other in the horizontal direction, and

is configured such that the electric signals output from the plurality of pixel units which shares the shared VSL are added on the shared VSL.

### REFERENCE SIGNS LIST

1 Optical system
2 Image sensor
3 Memory
4 Signal processor
5 Output unit
6 Control unit
11 Pixel access unit
12 Column I/F unit
13 Signal processor
14 Timing control unit
21 Pixel array unit
22 Row control unit
23 Column processor
24 Column control unit
41 Pixel unit 41
42 VSL
43 Row signal line
51 DAC
52 ADC
61 PD
62 to 66 FET
67, 68 FD
101 Substrate supporting material
102 Metal/contact layer
103 CS layer
104 Poly layer
105 Si layer
106 OCCF
107 OCL

What is claimed is:

1. A solid-state imaging device comprising:
a pixel array unit in which pixel units which output electric signals obtained by photoelectric conversion are arranged at least in a horizontal direction; and
a shared VSL being a vertical signal line (VSL) shared by a plurality of pixel units adjacent to each other in the horizontal direction,
the solid-state imaging device being configured such that the electric signals output from the plurality of pixel units which shares the shared VSL are added on the shared VSL.

2. The solid-state imaging device according to claim 1, wherein the pixel unit includes a plurality of pixels being sharing pixels which share a floating diffusion (FD) and outputs the electric signals obtained by the photoelectric conversion by the pixels.

3. The solid-state imaging device according to claim 2, wherein the pixel unit outputs an addition signal obtained by FD addition to add the electric signals obtained by two or more pixels sharing the FD by utilizing the FD.

4. The solid-state imaging device according to claim 3, wherein the electric signals obtained by two or more pixels arranged in a vertical direction out of the plurality of pixels included in the pixel unit are added in the FD addition.

5. The solid-state imaging device according to claim 4, wherein
the pixel unit includes a transistor including a diffusion layer, and
diffusion layers of transistors of the pixel units adjacent to each other in the horizontal direction are connected by a wiring line and the wiring line is connected to the shared VSL, so that the pixel units adjacent to each other in the horizontal direction share the shared VSL.

6. The solid-state imaging device according to claim 5, wherein the transistor is a selection transistor.

7. The solid-state imaging device according to claim 6, further comprising:
a VSL for full pixel reading to read each of the electric signals obtained by the plurality of pixels included in the pixel unit.

8. The solid-state imaging device according to claim 4, wherein
the pixel unit includes a transistor including a diffusion layer, and
one diffusion layer is shared as diffusion layers of transistors of the pixel units adjacent to each other in the horizontal direction and is connected to the shared VSL, so that the pixel units adjacent to each other in the horizontal direction share the shared VSL.

9. The solid-state imaging device according to claim 8, wherein the transistor is a selection transistor.

10. The solid-state imaging device according to claim 9, further comprising:
a VSL for full pixel reading to read each of the electric signals obtained by the plurality of pixels included in the pixel unit.

11. A signal processing method comprising:
adding electric signals output from a plurality of pixel units sharing a shared VSL on the shared VSL of
a solid-state imaging device including:
a pixel array unit in which pixel units which output the electric signals obtained by photoelectric conversion are arranged at least in a horizontal direction; and
the shared VSL being a vertical signal line (VSL) shared by the plurality of pixel units adjacent to each other in the horizontal direction.

12. An electronic device comprising:
an optical system which condenses light; and
a solid-state imaging device which receives light and takes an image, wherein the solid-state imaging device includes:
a pixel array unit in which pixel units which output electric signals obtained by photoelectric conversion are arranged at least in a horizontal direction; and
a shared VSL being a vertical signal line (VSL) shared by a plurality of pixel units adjacent to each other in the horizontal direction, and
is configured such that the electric signals output from the plurality of pixel units which shares the shared VSL are added on the shared VSL.
